(19) United States
(12) Patent Application Publication
(10) Pub. No.: US 2018/0053873 A1
(43) Pub. Date: Feb. 22, 2018

(54) Process for the production of solar cells using printable doping media which inhibit the diffusion of phosphorus

(71) Applicant: Merck Patent GmbH, Darmstadt (DE)

(72) Inventors: Oliver DOLL, Dietzenbach (DE); Ingo KOEHLER, Darmstadt (DE); Sebastian BARTH, Darmstadt (DE)

(73) Assignee: Merck Patent GmbH, Darmstadt (DE)

(21) Appl. No.: 15/565,970

(22) PCT Filed: Mar. 24, 2016
(86) PCT No.: PCT/EP2016/000517

§ 371 Date: Oct. 12, 2017

(30) Foreign Application Priority Data
Apr. 15, 2015 (EP) 15001072.6
Aug. 12, 2015 (EP) 15180689.0

(51) Int. Cl. H01L 31/18; H01L 21/225; H01L 21/22; H01L 31/0288; H01L 31/068; C09D 11/023; C09D 11/037

(52) U.S. Cl. CPC H01L 31/1804; H01L 21/2255; H01L 21/2225; C09D 11/037; H01L 31/068; C09D 11/023; H01L 31/0288

(57) ABSTRACT

The present invention relates to a novel printable medium in the form of a hybrid sol and/or gel based on precursors of inorganic oxides for use in a simplified process for the production of solar cells, in which the medium according to the invention functions both as doping medium and also as diffusion barrier.

The present invention relates to a novel printable medium in the form of a hybrid sol and/or gel on the basis of precursors of inorganic oxides for use in a simplified process for the production of solar cells in which the medium according to the invention functions both as doping medium and also as diffusion barrier.

### PRIOR ART

The production of simple solar cells or the solar cells which are currently represented with the greatest market share in the market comprises the essential production steps outlined below:

### 1) Saw-Damage Etching and Texture

A silicon wafer (monocrystalline, multicrystalline or quasi-monocrystalline, base doping p or n type) is freed from adherent saw damage by means of etching methods and “simultaneously” textured, generally in the same etching bath. Texturing is in this case taken to mean the creation of a preferentially aligned surface (nature) as a consequence of the etching step or simply the intentional, but not particularly aligned roughening of the wafer surface. As a consequence of the texturing, the surface of the wafer now acts as a diffuse reflector and thus reduces the directed reflection, which is dependent on the wavelength and on the angle of incidence, ultimately resulting in an increase in the absorbed proportion of the light incident on the surface and thus an increase in the conversion efficiency of the solar cell.

The above-mentioned etching solutions for the treatment of the silicon wafers typically consist, in the case of monocrystalline wafers, of dilute potassium hydroxide solution to which isopropyl alcohol has been added as solvent. Other alcohols having a higher vapour pressure or a higher boiling point than isopropyl alcohol may also be added instead if this enables the desired etching result to be achieved. The desired etching result obtained is typically a morphology which is characterised by pyramids having a square base which are randomly arranged, or rather etched out of the original surface. The density, the height and thus the base area of the pyramids can be partly influenced by a suitable choice of the above-mentioned components of the etching solution, the etching temperature and the residence time of the wafers in the etching tank. The texturing of the monocrystalline wafers is typically carried out in the temperature range from 70-<90° C., where up to 10 μm of material per wafer side can be removed by etching.

In the case of multicrystalline silicon wafers, the etching solution can consist of potassium hydroxide solution having a moderate concentration (10-15%). However, this etching technique is hardly still used in industrial practice. More frequently, an etching solution consisting of nitric acid, hydrofluoric acid and water is used. This etching solution can be modified by various additives, such as, for example, sulfuric acid, phosphoric acid, acetic acid, N-methylpyrrolidone, and also surfactants, enabling, inter alia, wetting properties of the etching solution and also its etching rate to be specifically influenced. These acidic etch mixtures produce a morphology of nested etching trenches on the surface. The etching is typically carried out at temperatures in the range between 4° C. and <10° C., and the amount of material removed by etching here is generally 4 μm to 6 μm.

Immediately after the texturing, the silicon wafers are cleaned intensively with water and treated with dilute hydrofluoric acid in order to remove the chemical oxide layer formed as a consequence of the preceding treatment steps and contaminants absorbed and adsorbed therein and also thereon, in preparation for the subsequent high-temperature treatment.

### 2) Diffusion and Doping

The wafers etched and cleaned in the preceding step (in this case p-type base doping) are treated with vapour consisting of phosphorus oxide at elevated temperatures, typically between 750° C. and <1000° C. During this operation, the wafers are exposed to a controlled atmosphere consisting of dried nitrogen, dried oxygen and phosphoryl chloride in a quartz tube in a tubular furnace. To this end, the wafers are introduced into the quartz tube at temperatures between 600 and 700° C. The gas mixture is transported through the quartz tube. During the transport of the gas mixture through the strongly warmed tube, the phosphoryl chloride decomposes to give a vapour consisting of phosphorus oxide (for example P₂O₅) and chlorine gas. The phosphorus oxide vapour precipitates, inter alia, on the wafer surfaces (coating). At the same time, the silicon surface is oxidised at these temperatures with formation of a thin oxide layer. The precipitated phosphorus oxide is embedded in this layer, causing mixed oxide of silicon dioxide and phosphorus oxide to form on the wafer surface. This mixed oxide is known as phosphosilicate glass (PSG). This PSG has different softening points and different diffusion constants with respect to the phosphorus oxide depending on the concentration of the phosphorus oxide present. The mixed oxide serves as diffusion source for the silicon wafer, where the phosphorus oxide diffuses in the course of the diffusion in the direction of the interface between PSG and silicon wafer, where it is reduced to phosphorus by reaction with the silicon at the wafer surface (silicothermally). The phosphorus formed in this way has a solubility in silicon which is orders of magnitude higher than in the glass matrix from which it has been formed and thus preferentially dissolves in the silicon owing to the very high segregation coefficient. After dissolution, the phosphorus diffuses in the silicon along the concentration gradient into the volume of the silicon. In this diffusion process, concentration gradients in the order of 10⁵ form between typical surface concentrations of 10²¹ atoms/cm² and the base doping in the region of 10¹⁶ atoms/cm². The typical diffusion depth is 250 to 500 nm and is dependent on the diffusion temperature selected (for example 880° C.), and the total exposure duration (heating & coating phase & drive-in phase & cooling) of the wafers in the strongly warmed atmosphere. During the coating phase, a PSG layer forms which typically has a layer thickness of 40 to 60 nm. The coating of the wafers with the PSG, during which diffusion into the volume of the silicon also already takes place, is followed by the drive-in phase. This can be decoupled from the coating phase, but is in practice generally coupled directly to the coating in terms of time and is therefore usually also carried out at the same temperature. The composition of the gas mixture here is adapted in such a way that the further supply of phosphoryl chloride is suppressed. During drive-in, the surface of the silicon is oxidised further by the oxygen present in the gas mixture, causing a phosphorus oxide-depleted silicon dioxide layer which likewise comprises phosphorus oxide to be generated between the actual doping source, the highly phosphorus oxide-enriched PSG, and the silicon wafer. The growth of this layer is very much faster in relation to the mass flow of the dopant from the source (PSG), since the oxide growth is accelerated by the high surface doping of the wafer itself (acceleration by one to two orders of magnitude). This enables depletion or separation of the doping source to be achieved in a certain manner, permeation of which with phosphorus oxide diffusing on is influenced by the material flow, which is dependent on the temperature and thus the diffusion coefficient. In this way, the doping of the silicon can be controlled in certain limits. A typical diffusion duration consisting of coating phase and drive-in phase is, for example, 25 minutes. After this treatment, the tubular furnace is automatically cooled, and the wafers can be removed from the process tube at temperatures between 600° C. and 700° C.

In the case of boron doping of the wafers in the form of n-type base doping, a different method is used, which will not be explained separately here. The doping in these cases is carried out, for example, with boron trichloride or boron tribromide. Depending on the choice of the composition of the gas atmosphere employed for the doping, the formation of a so-called boron skin on the wafers may be observed. This boron skin is dependent on various influencing factors: crucially the doping atmosphere, the temperature, the doping duration, the source concentration and the coupled (or linear-combined) parameters mentioned above.

In such diffusion processes, it goes without saying that the wafers used cannot contain any regions of preferred diffusion and doping (apart from those which are formed by inhomogeneous gas flows and resultant gas pockets of inhomogeneous composition) if the substrates have not previously been subjected to a corresponding pretreatment (for example structuring thereof with diffusion-inhibiting and/or -suppressing layers and materials).

For completeness, it should also be pointed out here that there are also further diffusion and doping technologies which have become established to different extents in the production of crystalline solar cells based on silicon. Thus, mention may be made of:
ion implantation,
doping promoted via the gas-phase deposition of mixed oxides, such as, for example, those of PSG and BSG (borosilicate glass), by means of APCVD, PECVD, MOCVD and LPCVD processes,
(co)sputtering of mixed oxides and/or ceramic materials and hard materials (for example boron nitride), gas-phase deposition of the latter two, purely thermal gas-phase deposition starting from solid dopant sources (for example boron oxide and boron nitride), and
liquid-phase deposition of liquids (inks) and pastes having a doping action.

The latter are frequently used in so-called inline doping, in which the corresponding pastes and inks are applied by means of suitable methods to the wafer side to be doped. After or also even during the application, the solvents present in the compositions employed for the doping are removed by temperature and/or vacuum treatment. This leaves the actual dopant behind on the wafer surface. Liquid doping sources which can be employed are, for example, dilute solutions of phosphoric or boric acid, and also sol-gel-based systems or also solutions of polymeric borazil compounds. Corresponding doping pastes are characterised virtually exclusively by the use of additional thickening polymers, and comprise dopants in suitable form. The evaporation of the solvents from the above-mentioned doping media is usually followed by treatment at high temperature, during which undesired and interfering additives, but ones which are necessary for the formulation, are either “burnt” and/or pyrolysed. The removal of solvents and the burning-out may, but do not have to, take place simultaneously. The coated substrates subsequently usually pass through a through-flow furnace at temperatures between 800° C. and 1000° C., where the temperatures may be slightly increased compared with gas-phase diffusion in the tubular furnace in order to shorten the passage time. The gas atmosphere prevailing in the through-flow furnace may differ in accordance with the requirements of the doping and may consist of dry nitrogen, dry air, a mixture of dry oxygen and dry nitrogen and/or, depending on the design of the furnace to be passed through, zones of one or other of the above-mentioned gas atmospheres. Further gas mixtures are conceivable, but currently do not have major importance industrially. A characteristic of inline diffusion is that the coating and drive-in of the dopant can in principle take place decoupled from one another.

### 3) Removal of the Dopant Source and Optional Edge Insulation

The wafers present after the doping are coated on both sides with more or less glass on both sides of the surface. “More or less” in this case refers to modifications which can be applied during the doping process: double-sided diffusion vs. quasi-single-sided diffusion promoted by back-to-back arrangement of two wafers in one location of the process boats used. The latter variant enables predominantly single-sided doping, but does not completely suppress diffusion on the back. In both cases, the current state of the art is removal of the glasses present after the doping from the surfaces by means of etching in dilute hydrofluoric acid. To this end, the wafers are on the one hand reloaded in batches into wet-process boats and with the aid of the latter dipped into a solution of dilute hydrofluoric acid, typically 2% to 5%, and left therein until either the surface has been completely freed from the glasses, or the process cycle duration, which represents a sum parameter of the requisite etching duration and the process automation by machine, has expired. The complete removal of the glasses can be established, for example, from the complete dewetting of the silicon wafer surface by the dilute aqueous hydrofluoric acid solution. The complete removal of a PSG is achieved within 210 seconds at room temperature under these process conditions, for example using 2% hydrofluoric acid solution. The etching of corresponding BSGs is slower and requires longer process times and possibly also higher concentrations of the hydrofluoric acid used. After the etching, the wafers are rinsed with water.

On the other hand, the etching of the glasses on the wafer surfaces can also be carried out in a horizontally operating process, in which the wafers are introduced in a constant flow into an etcher in which the wafers pass horizontally through the corresponding process tanks (inline machine). In this case, the wafers are conveyed on rollers either through the process tanks and the etching solutions present therein, or the etch media are transported onto the wafer surfaces by means of roller application. The typical residence time of the wafers during etching of the PSG is about 90 seconds, and the hydrofluoric acid used is somewhat more highly concentrated than in the case of the batch process in order to compensate for the shorter residence time as a consequence of an increased etching rate. The concentration of the hydrofluoric acid is typically 5%. The tank temperature may optionally additionally be slightly increased compared with room temperature (>25° C.<50° C.).

In the process outlined last, it has become established to carry out the so-called edge insulation sequentially at the same time, giving rise to a slightly modified process flow: edge insulation→glass etching. Edge insulation is a technical necessity in the process which arises from the system-inherent characteristic of double-sided diffusion, also in the case of intentional single-sided back-to-back diffusion. A large-area parasitic p-n junction is present on the (later) back of the solar cell, which is, for process-engineering reasons, removed partially, but not completely, during the later processing. As a consequence of this, the front and back of the solar cell will have been short-circuited via a parasitic and residue p-n junction (tunnel contact), which reduces the conversion efficiency of the later solar cell. For removal of this junction, the wafers are passed on one side over an etching solution consisting of nitric acid and hydrofluoric acid. The etching solution may comprise, for example, sulfuric acid or phosphoric acid as secondary constituents. Alternatively, the etching solution is transported (conveyed) via rollers onto the back of the wafer. About 1 μm of silicon (including the glass layer present on the surface to be treated) is typically removed by etching in this process at temperatures between 4° C. and 8° C. In this process, the glass layer still present on the opposite side of the wafer serves as a mask, which provides a certain protection against overetching onto this side. This glass layer is subsequently removed with the aid of the glass etching already described.

In addition, the edge insulation can also be carried out with the aid of plasma etching processes. This plasma etching is then generally carried out before the glass etching. To this end, a plurality of wafers are stacked one on top of the other, and the outside edges are exposed to the plasma. The plasma is fed with fluorinated gases, for example tetrafluoromethane. The reactive species occurring on plasma decomposition of these gases etch the edges of the wafer. In general, the plasma etching is then followed by the glass etching.

4) Coating of the Front Surface with an Antireflection Layer

After the etching of the glass and the optional edge insulation, the front surface of the later solar cells is coated with an antireflection coating, which usually consists of amorphous and hydrogen-rich silicon nitride. Alternative antireflection coatings are conceivable. Possible coatings may consist of titanium dioxide, magnesium fluoride, tin dioxide and/or corresponding stacked layers of silicon dioxide and silicon nitride. However, antireflection coatings having a different composition are also technically possible. The coating of the wafer surface with the above-mentioned silicon nitride essentially fulfils two functions: on the one hand the layer generates an electric field owing to the numerous incorporated positive charges, which can keep charge carriers in the silicon away from the surface and can considerably reduce the recombination rate of these charge carriers at the silicon surface (field-effect passivation), on the other hand this layer generates a reflection-reducing property, depending on its optical parameters, such as, for example, refractive index and layer thickness, which contributes to it being possible for more light to be coupled into the later solar cell. The two effects can increase the conversion efficiency of the solar cell. Typical properties of the layers currently used are: a layer thickness of ˜80 nm on use of exclusively the above-mentioned silicon nitride, which has a refractive index of about 2.05. The antireflection reduction is most clearly apparent in the light wavelength region of 600 nm. The directed and undirected reflection here exhibits a value of about 1% to 3% of the originally incident light (perpendicular incidence to the surface perpendicular of the silicon wafer).

The above-mentioned silicon nitride layers are currently generally deposited on the surface by means of the direct PECVD process. To this end, a plasma into which silane and ammonia are introduced is ignited in an argon gas atmosphere. The silane and the ammonia are reacted in the plasma via ionic and free-radical reactions to give silicon nitride and at the same time deposited on the wafer surface. The properties of the layers can be adjusted and controlled, for example, via the individual gas flows of the reactants. The deposition of the above-mentioned silicon nitride layers can also be carried out with hydrogen as carrier gas and/or the reactants alone. Typical deposition temperatures are in the range between 300° C. and 400° C. Alternative deposition methods can be, for example, LPCVD and/or sputtering.

### 5) Production of the Front Surface Electrode Grid

After deposition of the antireflection layer, the front surface electrode is defined on the wafer surface coated with silicon nitride. In industrial practice, it has become established to produce the electrode with the aid of the screen-printing method using metallic sinter pastes. However, this is only one of many different possibilities for the production of the desired metal contacts.

In screen-printing metallisation, a paste which is highly enriched with silver particles (silver content ≦80%) is generally used. The sum of the remaining constituents arises from the rheological assistants necessary for formulation of the paste, such as, for example, solvents, binders and thickeners. Furthermore, the silver paste comprises a special glass-frit mixture, usually oxides and mixed oxides based on silicon dioxide, borosilicate glass and also lead oxide and/or bismuth oxide. The glass frit essentially fulfils two functions: it serves on the one hand as adhesion promoter between the wafer surface and the mass of the silver particles to be sintered, on the other hand it is responsible for penetration of the silicon nitride top layer in order to facilitate direct ohmic contact with the underlying silicon. The penetration of the silicon nitride takes place via an etching process with subsequent diffusion of silver dissolved in the glass-frit matrix into the silicon surface, whereby the ohmic contact formation is achieved. In practice, the silver paste is deposited on the wafer surface by means of screen printing and subsequently dried at temperatures of about 200° C. to 300° C. for a few minutes. For completeness, it should be mentioned that double-printing processes are also used industrially, which enable a second electrode grid to be printed with accurate registration onto an electrode grid generated during the first printing step. The thickness of the silver metallisation is thus increased, which can have a positive influence on the conductivity in the electrode grid. During this drying, the solvents present in the paste are expelled from the paste. The printed wafer subsequently passes through a through-flow furnace. An furnace of this type generally has a plurality of heating zones which can be activated and temperature-controlled independently of one another. During passivation of the through-flow furnace, the wafers are heated to temperatures up to about 950° C. However, the individual wafer is generally only subjected to this peak temperature for a few seconds. During the remainder of the through-flow phase, the wafer has temperatures of 600° C. to 800° C. At these temperatures, organic accompanying substances present in the silver paste, such as, for example, binders, are burnt out, and the etching of the silicon nitride layer is initiated. During the short time interval of prevailing peak temperatures, the contact formation with the silicon takes place. The wafers are subsequently allowed to cool.

The contact formation process outlined briefly in this way is usually carried out simultaneously with the two remaining contact formations (cf. 6 and 7), which is why the term co-firing process is also used in this case.

The front surface electrode grid consists per se of thin fingers (typical number ≧68) which have a width of typically 80 μm to 140 μm, and also busbars having widths in the range from 1.2 mm to 2.2 mm (depending on their number, typically two to three). The typical height of the printed silver elements is generally between 10 μm and 25 μm. The aspect ratio is rarely greater than 0.3.

### 6) Production of the Back Surface Busbars

The back surface busbars are generally likewise applied and defined by means of screen-printing processes. To this end, a similar silver paste to that used for the front surface metallisation is used. This paste has a similar composition, but comprises an alloy of silver and aluminium in which the proportion of aluminium typically makes up 2%. In addition, this paste comprises a lower glass-frit content. The busbars, generally two units, are printed onto the back of the wafer by means of screen printing with a typical width of 4 mm and are compacted and sintered as already described under point 5.

### 7) Production of the Back Surface Electrode

The back surface electrode is defined after the printing of the busbars. The electrode material consists of aluminium, which is why an aluminium-containing paste is printed onto the remaining free area of the wafer back by means of screen printing with an edge separation <1 mm for definition of the electrode. The paste is composed of ≦80% of aluminium. The remaining components are those which have already been mentioned under point 5 (such as, for example, solvents, binders, etc.). The aluminium paste is bonded to the wafer during the co-firing by the aluminium particles beginning to melt during the warming and silicon from the wafer dissolving in the molten aluminium. The melt mixture functions as dopant source and releases aluminium to the silicon (solubility limit: 0.016 atom percent), where the silicon is p⁺-doped as a consequence of this drive-in. During cooling of the wafer, a eutectic mixture of aluminium and silicon, which solidifies at 577° C. and has a composition having a mole fraction of 0.12 of Si, deposits, inter alia, on the wafer surface.

As a consequence of the drive-in of the aluminium into the silicon, a highly doped p-type layer, which functions as a type of mirror (“electric mirror”) on parts of the free charge carriers in the silicon, forms on the back of the wafer. These charge carriers cannot overcome this potential wall and are thus kept away from the back wafer surface very efficiently, which is thus evident from an overall reduced recombination rate of charge carriers at this surface. This potential wall is generally referred to as “back surface field”.

The sequence of the process steps described under points 5, 6 and 7 may, but does not have to, correspond to the sequence outlined here. It is evident to the person skilled in the art that the sequence of the outlined process steps can in principle be carried out in any conceivable combination.

### 8) Optional Edge Insulation

If the edge insulation of the wafer has not already been carried out as described under point 3, this is typically carried out with the aid of laser-beam methods after the co-firing. To this end, a laser beam is directed at the front of the solar cell, and the front surface p-n junction is parted with the aid of the energy coupled in by this beam. Cut trenches having a depth of up to 15 μm are generated here as a consequence of the action of the laser. Silicon is removed from the treated site via an ablation mechanism or ejected from the laser trench. This laser trench typically has a width of 30 μm to 60 μm and is about 200 μm away from the edge of the solar cell.

After production, the solar cells are characterised and classified in individual performance categories in accordance with their individual performances.

The person skilled in the art is familiar with solar-cell architectures with both n-type and also p-type base material. These solar cell types include, inter alia,
PERC solar cells,
PERL solar cells,
PERT solar cells,
MWT-PERT and MWT-PERL solar cells derived therefrom,
bifacial solar cells,
back surface contact cells,
back surface contact cells with interdigital contacts (IBC cells).

The choice of alternative doping technologies, as an alternative to the gas-phase doping already described in the introduction, is generally also incapable of solving the problem of the creation of locally differently doped regions on the silicon substrate. Alternative technologies which may be mentioned here are the deposition of doped glasses, or of amorphous mixed oxides, by means of PECVD and APCVD processes. Thermally induced doping of the silicon located beneath these glasses can easily be achieved from these glasses. In order to create locally differently doped regions, however, these glasses must be etched by means of mask processes in order to produce the corresponding structures from them. Alternatively, structured diffusion barriers against the deposition of the glasses can be deposited on the silicon wafers in order thus to define the regions to be doped. However, it is disadvantageous in this process that in each case only one polarity (n or p) can be achieved in the doping of the substrates.

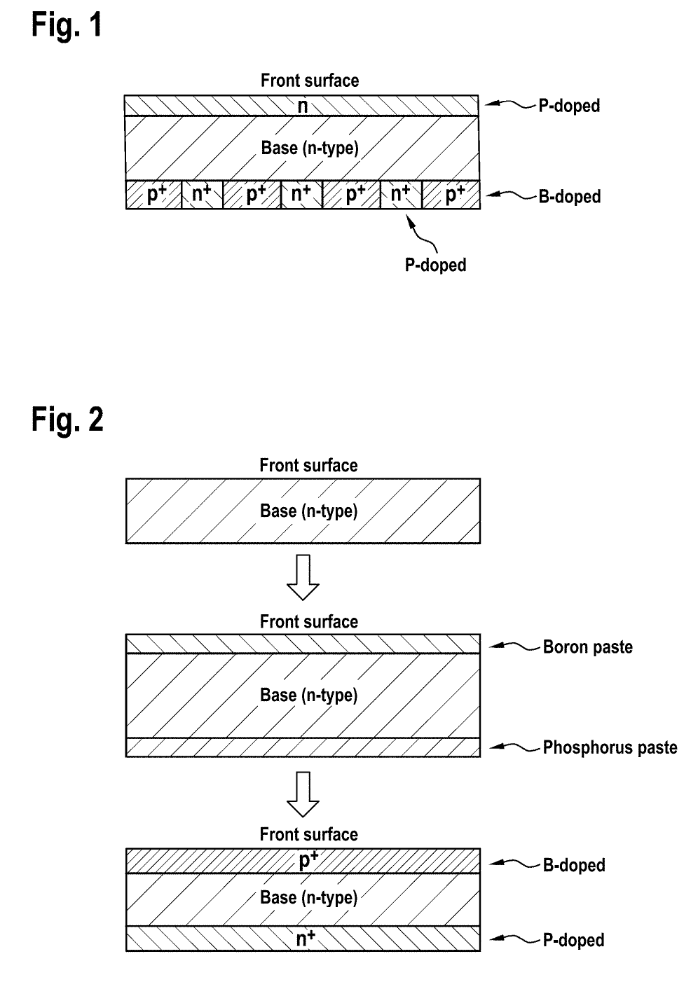

FIG. 1: shows a simplified cross-section through an IBC solar cell (not to scale, without surface texture, without antireflection and passivation layers, without back-surface metallisation). The alternating pn junctions can have different arrangements, such as, for example, directly adjacent to one another, or with gaps with intrinsic regions.

Let us concentrate below in a simplified manner on a possible excerpt of the production process of a so-called IBC solar cell (FIG. 1). This excerpt and thus outlined part-process makes no claim to completeness or to exclusivity in this consideration. Deviations and modifications of the process chain described can easily be imagined and also achieved. The starting point is a CZ wafer, which has, for example, a surface which is alkaline-polished or saw damage-etched on one side. This wafer is coated over the entire surface on one side, which is not polished and is thus the later front surface, by means of a CVD oxide of suitable thickness, such as, for example, 200 nm or more. After the coating with the CVD oxide on one side, the wafer is subjected to B diffusion in a conventional tubular furnace, by means of, for example, boron tribromide as precursor. After the boron diffusion, the wafer must be locally structured on the now-diffused back surface in order to define and ultimately to create the regions for the later contacts to the base and for the production of the local back surface field diffused with phosphorus in this case. This structuring can be achieved, for example, with the aid of a laser, which locally ablates the doped glass present on the back surface. The use of laser radiation in the production of highly efficient solar cells is controversial owing to the damage to the bulk of the silicon wafer. For simplicity, however, let us assume that it were possible and there were or are no further fundamental problems. The indisputably damaged silicon present at least at the surface must then, after the laser treatment, be removed with the aid of an alkaline damage etch. In practical terms, the boron emitter present at this point is simultaneously dissolved and removed (if it were in this case likewise assumed that, as usually known, highly boron-doped silicon is not an etch stop for KOH-based etch solutions)—if it can justifiably be assumed that the remaining borosilicate glass (BSG) at the closed points represents adequate protection of the silicon against the KOH solution (etching rate of SiO₂ in 30% KOH at 80° C. is about 3 nm/min, this could be somewhat higher in KOH if a “disordered oxide” is assumed in the case of BSG). A plateau or a type of trench is etched into the silicon here. Alternatively, the base contacts to the later local back surface field could be created by applying an etch mask to the back surface, for example by means of screen printing, and subsequently treating the open points with the aid of two consecutive or even only one etching step: removal of the glass from one surface by etching in hydrofluoric acid and subsequent etching in KOH solution, or etching of both materials in one step. Either the etch mask and the doped glass or only the doped glass would subsequently be removed, in each case from one side on the back surface. A CVD oxide layer would subsequently be deposited on the back surface of the wafer and locally opened and structured, to be precise at the points at which the boron emitter had previously been removed. The wafers would subsequently be subjected to phosphorus diffusion. Depending on how the process parameters of this diffusion looked in detail, it would also only be necessary to carry out the structurings described above once, to be precise, for example, in a case where the performance of phosphorus diffusion would no longer influence the boron doping profile already obtained in the simultaneous presence of BSG glass, or would indeed influence it in a controllable manner. The wafers would subsequently be freed on one side from the protecting oxide on their front surface and subjected to weak phosphorus diffusion. For simplicity, it has been assumed at this point that the BSG glass present on the back surface is able to remain on the wafer surface and would thus not cause any further interferences or influences. After the weak diffusion on the front surface, the wafers are etched with hydrofluoric acid and all oxides and glasses are removed. In total, the process outlined above is characterised by the following steps and their total number (described in simplified terms for structuring by means of a laser process; in the case of the use of etch resists, printing and stripping of the resist would also have to be added):

1. Oxide mask over the entire front surface
2. Boron diffusion
3. Structuring and etching of the back surface
4. Oxide mask over the entire back surface
5. Structuring of the back surface
6. Phosphorus diffusion
7. Removal of oxide mask on the front surface
8. Phosphorus diffusion
9. Removal of all glasses

In total, nine process steps are needed in order to achieve structured doping of the wafer. By contrast, depending on the counting method, eight process steps are needed for the production of an entire standard aluminium BSF solar cell. In the production of IBC cells, other possibilities may be able to be used, the effort for achieving structured dopings is very high in each case and is expensive in each of these cases, in some cases just as expensive as the production of a single standard aluminium BSF solar cell. The further spread of this cell technology will in each case be dependent on the reduction of process costs, which will therefore significantly profit from the establishment of simplifying process alternatives which nevertheless allow high cell efficiencies.

### OBJECT OF THE PRESENT INVENTION

The doping technologies usually used in the industrial production of solar cells, especially by gas phase-promoted diffusion with reactive precursors, such as phosphoryl chloride and/or boron tribromide, do not enable local dopings and/or locally different dopings to be generated on silicon wafers in a targeted manner. The creation of such structures using known doping technologies is only possible through complex and expensive structuring of the substrates. During the structuring, various masking processes must be matched to one another, which makes industrial mass production of such substrates very complex. For this reason, concepts for the production of solar cells which require such structuring have hitherto not been able to establish themselves. The object of the present invention is therefore to provide an inexpensive process which is simple to carry out, and a medium which can be employed in this process, whereby these problems and the masking steps which are normally necessary are obsolete and are thus eliminated. In addition, the doping source which can be applied locally is distinguished by the fact that it can preferably be applied to the wafer surfaces by means of known printing technologies which are established in solar cell manufacturing technology. In addition, the special feature of the process according to the invention arises from the fact that the printable doping media used have a diffusion-inhibiting action against the gas phase dopant phosphoryl chloride which is conventionally used in industry, and also similar dopants (which, correctly expressed, can be dopants which are converted into phosphorus pentoxide as a consequence of their combustion in the gas phase) and thus allow in the simplest manner simultaneous, but also any desired sequential diffusions and dopings with two dopants for either simultaneous or sequential doping of opposite polarities in silicon.

### BRIEF DESCRIPTION OF THE INVENTION

The present invention therefore relates to printable hybrid sols and/or gels based on precursors, such as of silicon dioxide, aluminium oxide and boron oxide, which are printed onto silicon surfaces for the purposes of local and/or full-area diffusion and doping on one side by means of suitable printing processes in the production of solar cells, preferably of highly efficient solar cells doped in a structured manner, dried and subsequently brought to specific doping of the substrate itself by means of a suitable high-temperature process for release of the boron oxide precursor present in the hybrid gel to the substrate located beneath the hybrid gel. The printable hybrid sols and/or gels are based on precursors of the following oxide materials:
a) silicon dioxide: symmetrically and asymmetrically mono- to tetrasubstituted carboxy-, alkoxy- and alkoxyalkylsilanes, explicitly containing alkylalkoxysilanes, in which the central silicon atom can have a degree of substitution of [lacuna] by at least one hydrogen atom bonded directly to the silicon atom, such as, for example, triethoxysilane, and where furthermore a degree of substitution relates to the number of possible carboxyl and/or alkoxy groups present, which, both in the case of alkyl and/or alkoxy and/or carboxyl groups, contain individual or different saturated, unsaturated branched, unbranched aliphatic, alicyclic and aromatic radicals, which may in turn be functionalised at any desired position of the alkyl, alkoxide or carboxyl radical by heteroatoms selected from the group O, N, S, Cl and Br, and mixtures of the above-mentioned precursors; individual compounds which satisfy the above-mentioned demands are: tetraethyl orthosilicate and the like, triethoxysilane, ethoxytrimethylsilane, dimethyldimethoxysilane, dimethyldiethoxysilane, triethoxyvinylsilane, bis[triethoxysilyl]ethane and bis[diethoxymethylsilyl]ethane
b) aluminium oxide: symmetrically and asymmetrically substituted aluminium alcoholates (alkoxides), such as aluminium triethanolate, aluminium triisopropylate, aluminium tri-sec-butylate, aluminium tributylate, aluminium triamylate and aluminium triisopentanolate, aluminium tris(β-diketones), such as aluminium acetylacetonate or aluminium tris(1,3-cyclohexanedionate), aluminium tris(β-ketoesters), aluminium mono-acetylacetonate monoalcoholate, aluminium tris(hydroxyquinolate), aluminium soaps, such as mono- and dibasic aluminium stearate and aluminium tristearate, aluminium carboxylates, such as basic aluminium acetate, aluminium triacetate, basic aluminium formate, aluminium triformate and aluminium trioctanoate, aluminium hydroxide, aluminium metahydroxide and aluminium trichloride and the like, and mixtures thereof
c) boron oxide: diboron oxide, simple alkyl borates, such as triethyl borate, triisopropyl borate, boric acid esters of functionalised 1,2-glycols, such as, for example, ethylene glycol, functionalised 1,2,3-triols, such as, for example, glycerol, functionalised 1,3-glycols, such as, for example, 1,3-propanediol, boric acid esters with boric acid esters which contain the above-mentioned structural motifs as structural sub-units, such as, for example, 2,3-dihydroxysuccinic acid and enantiomers thereof, boric acid esters of ethanolamine, diethanolamine, triethanolamine, propanolamine, dipropanolamine and tripropanolamine, mixed anhydrides of boric acid and carboxylic acids, such as, for example, tetraacetoxy diborate, boric acid, metaboric acid, and mixtures of the above-mentioned precursors,
   which are brought to partial or complete intra- and/or interspecies condensation under water-containing or anhydrous conditions with the aid of the sol-gel technique, either simultaneously or sequentially, where the degree of gelling of the hybrid sols and gels formed is controlled specifically and influenced in the desired manner as a consequence of the condensation conditions set, such as precursor concentrations, water content, catalyst content, reaction temperature and time, the addition of condensation-controlling agents, such as, for example, various above-mentioned complexing agents and chelating agents, various solvents and individual volume fractions thereof, and by specific elimination of readily volatile reaction assistants and disadvantageous by-products, giving storage-stable, very readily printable and printing-stable formulations.

The printable hybrid sols and/or gels obtained in this way, as described in greater detail below, can be printed very well onto surfaces of silicon wafers. They can be processed and deposited onto corresponding surfaces by means of suitable printing processes, such as spin or dip coating, drop casting, curtain or slot-die coating, screen or flexographic printing, gravure, ink-jet or aerosol-jet printing, offset printing, microcontact printing, electrohydrodynamic dispensing, roller or spray coating, ultrasound spray coating, pipe-jet printing, laser transfer printing, pad printing, flat-bed screen printing and rotary screen printing. Corresponding printable hybrid sols and/or gels are particularly suitable for use as doping media for the treatment of silicon wafers for photovoltaic, microelectronic, micromechanical and micro-optical applications. In particular, these compositions exhibit advantageous properties for use for the production of PERC, PERL, PERT and IBC solar cells and others, where the solar cells have further architectural features, such as MWT, EWT, selective emitter, selective front surface field, selective back surface field and bifaciality.

The printable hybrid sols and/or gels according to the invention are boron-containing doping medium for silicon surfaces which, during the boron doping, simultaneously act as diffusion barrier or as diffusion-inhibiting layer against the undesired diffusion of phosphorus through these media themselves and completely block or inhibit corresponding diffusion to an adequate extent, so that the doping prevailing beneath these printed-on media is p type, i.e. boron-containing.

The object described above is accordingly achieved by the making available of the printable hybrid sols and/or gels described, but also by a suitable process for use for boron doping in the production of solar cells, where at the same time doping of the same areas by phosphorus is avoided.

The corresponding process is characterised in that, through suitable temperature treatment, doping of the printed substrate takes place simultaneously and/or sequentially and doping of the unprinted silicon wafer surfaces with dopants of the opposite polarity by means of conventional gas-phase diffusion is induced and where the printed-on hybrid sols and/or gels act as diffusion barrier against the dopants of the opposite polarity. In particular, the process according to the invention comprises the steps that
a. silicon wafers are printed locally on one or both sides or over the entire surface on one side with the hybrid sols and/or gels, the printed-on compositions are dried and compacted and subsequently subjected to subsequent gas-phase diffusion with, for example, phosphoryl chloride, giving p-type dopings in the printed regions and n-type dopings in the regions subjected exclusively to gas-phase diffusion, or
b. hybrid sol and/or gel deposited over a large area on the silicon wafer is compacted and local doping of the underlying substrate material is initiated from the dried and/or compacted paste with the aid of laser irradiation, followed by high-temperature diffusion and doping for the production of two-stage p-type doping levels in the silicon, or
c. the silicon wafer is printed locally on one side with hybrid sols and/or gels, where the structured deposition may optionally have alternating lines, the printed structures are dried and compacted, and the silicon wafer is subsequently coated over the entire surface on the same side of the wafer with the aid of PVD- and/or CVD-deposited phosphorus-doping dopant sources, where the printed structures of the hybrid sols and/or gels are encapsulated, and the entire overlapping structure is brought to structured doping of the silicon wafer by suitable high-temperature treatment and where the printed-on hybrid gel acts as diffusion barrier against the phosphorus-containing dopant source located on top and the dopant present therein, or
d. the silicon wafer is printed locally on one side with hybrid sols and/or gels, where the structured deposition may optionally have alternating lines, the printed structures are dried and compacted, and the silicon wafer is subsequently coated over the entire surface on the same side of the wafer with the aid of doping inks or doping pastes which have a phosphorus-doping action, where the printed structures of the hybrid sols and gels are encapsulated, and the entire overlapping structure is brought to structured doping of the silicon wafer by suitable high-temperature treatment, where the printed-on hybrid gel acts as diffusion barrier against the phosphorus-containing dopant source located on top and the dopant present therein.

### DETAILED DESCRIPTION OF THE INVENTION

Surprisingly, it has been found that printable hybrid sols and hybrid gels which consist at least of the following oxide precursors aluminium oxide, silicon dioxide and boron oxide are suitable as printable doping media for the local doping of silicon wafers and at the same time allow the phosphorus diffusion of the same wafers printed with these hybrid sols and gels, where the printed hybrid sols and gels act as efficient diffusion barrier against phosphorus diffusion. In other words, exclusive doping with boron is obtained under the co-diffusion conditions outlined in the regions printed with the sols and gels according to the invention, and exclusive doping with phosphorus is obtained in the regions exposed to the phosphorus oxide vapour having a doping action. The hybrid sols and gels according to the invention are described in the following documents: WO 2012/119686 A, WO2012119685 A1, WO2012119684 A, EP12703458.5 and EP12704232.3, and these should thus be regarded as part of the present disclosure.

The use of the hybrid sols and gels according to the invention thus enables simplified production of either solar cells which have structured dopings, such as, for example, IBC cells, or very generally of cells which have at least two different, not necessarily opposite dopings. Possible uses of the doping media according to the invention are outlined below.

FIG. 2 shows a simplified process flow chart for the production of a bifacial (in this case n-type) solar cell (PERT structure). The dopant source for the phosphorus diffusion was assumed to be a phosphorus paste, but it can equally well be any other source deposited over the entire surface, such as, for example, a doping ink or a CVD glass, a sputtered-on layer, epitactically deposited phosphorus-doped silicon, or a phosphorus-enriched silicon nitride layer. Instead of the boron paste according to the invention mentioned in the figure, it is of course also possible to use a boron doping ink according to the invention.

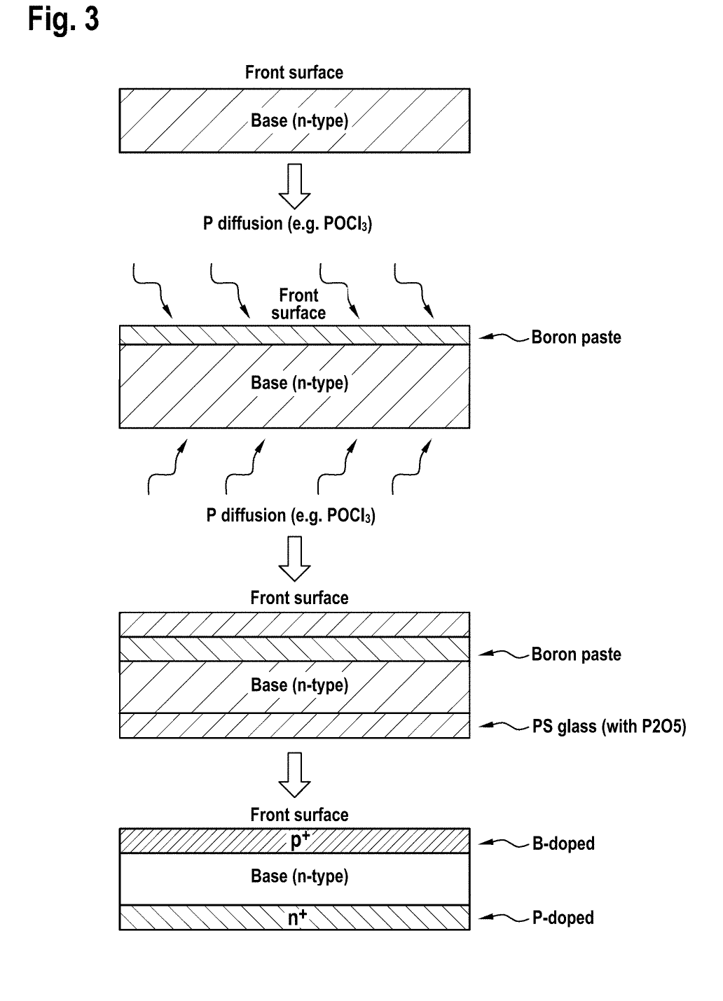

The production of a bifacial cell in accordance with FIG. 2 comprises the following essential process steps: two printing steps for the printing of the wafer surface, driving-in of the dopants, removal of the glass. A total of 4 process steps, compared with at least six, two of which are high-temperature steps, on use of the classical gas-phase diffusion process: masking on one side, diffusion with B, removal of the oxides, masking of the surface that has already been doped, diffusion with P, removal of the oxides. The use of the boron-containing doping media according to the invention results in a nominal reduction of the process steps necessary by one third compared with the classical process variant, which can thus be translated into more favourable production costs. The bifacial cell shown above can also be produced by the use of other dopant sources which can be deposited on one side, such as, for example, phosphorus-containing doping inks or a CVD glass, a sputtered-on layer, epitactically deposited and phosphorus-doped silicon, or a phosphorus-enriched silicon nitride layer, where the reverse procedure is of course also conceivable in principle in this connection. If the above-mentioned dopant sources acting on one side are used, a shortening of the process sequence can likewise be achieved: deposition of source 1, deposition of source 2, diffusion, removal of the residues. If both sources can be removed in one etching step, nominally the same effort as in the case already explained above arises: four process steps. This even applies in the case if the boron doping source according to the invention, ink (hybrid sol) or paste (hybrid gel), were to be replaced by one of the sources mentioned above, such as, for example, a CVD glass. However, the deposition of CVD glass as a vacuum process is a fairly expensive process step owing to the vacuum conditions. The same also applies to sputtering or epitactic deposition, meaning that the use of the boron doping media according to the invention has an inherent cost advantage owing to the less expensive deposition ability by means of printing steps. In principle, the wafer surface printed on both sides with doping media represents the least expensive possibility. In accordance with the composition according to the invention of the boron-containing hybrid sols and gels, parasitic dopings, which frequently take place and are to be observed from phosphorus-containing doping media, also do not represent a significant restriction of the possibility for the production of a bifacial solar cell by this route: the boron-containing hybrid sols and gels according to the invention, besides their function as dopant source, act as diffusion barriers for phosphorus diffusions. Surprisingly, it has therefore been observed that bifacial solar cells can be produced in a simple manner with the aid of the hybrid sols and gels according to the invention in accordance with the scheme outlined in FIG. 3.

FIG. 3 shows a simplified process flow chart for the production of a bifacial (in this case n-type) solar cell (PERT structure). A co-diffusion process using classical diffusion with phosphoryl chloride is depicted. The hybrid sols and gels according to the invention (here only mentioned as boron paste), besides their function as dopant source, act as diffusion barrier against phosphorus diffusion.

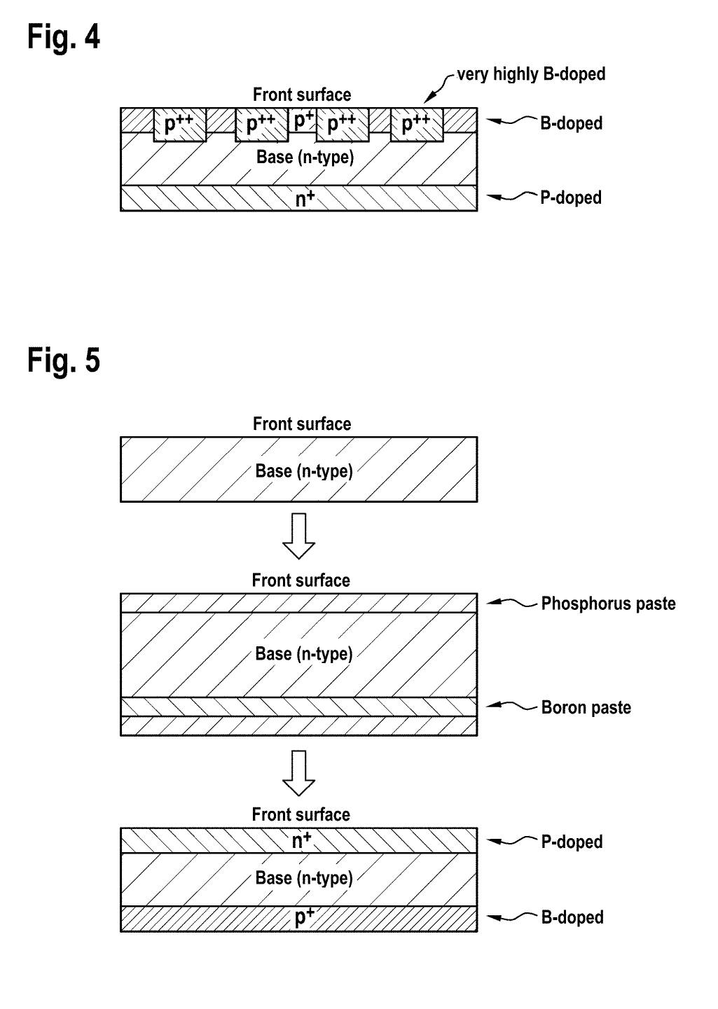

The hybrid sols and gels according to the invention act as diffusion barrier against phosphorus diffusion and thus protect the silicon wafer against penetration of this dopant from the gas phase into the surface regions of the wafer. At the same time, the boron-doping action of the hybrid sols and gels according to the invention is retained and thus enables on the one hand protection against penetration of phosphorus into the semiconductor and on the other hand effective diffusion and doping of the surfaces printed with these media with the desired and intended boron doping. Performance of the production of a bifacial solar cell in accordance with the principle outlined above results in the following essential process steps: printing of the boron source, co-diffusion with a phosphorus source from the gas phase, removal of the oxides and glasses—in total three process steps. This thus corresponds to a reduction of the process steps necessary for the production of a bifacial solar cell by half compared with the classical procedure (gas-phase diffusion with masking), and a reduction by a quarter of the process steps necessary compared with the case outlined above using, for example, CVD-based or similar dopant sources. Co-diffusion with the boron-containing hybrid sols and gels according to the invention as dopant sources thus represents the least expensive possibility for the production of bifacial solar cells. It goes without saying in this connection that, with inclusion of European Patent Applications 14004453.8 and 14004454.6, selectively doped structures, at least in the regions to be doped with boron, of the wafer can also be produced very simply (cf. FIG. 4).

FIG. 4 shows a simplified diagrammatic representation of a bifacial solar cell (n-type) with selective or two-stage doping (selective boron emitter) in the region of the boron emitter.

The following figures depict the process sequences already outlined for the bifacial n-type solar cells. FIGS. 5 to 7 show the possible process sequences and the results thereof for p-type wafers as base material. The conclusions which can basically be derived for these process sequences are the same as already stated for the case of the production of bifacial n-type cells.

FIG. 5 shows a simplified process flow chart for the production of a possible bifacial (in this case p-type) solar cell (PERT structure). The dopant source for the phosphorus diffusion was assumed to be a phosphorus paste, but it can equally well be any other source deposited over the entire surface, such as, for example, a doping ink or a CVD glass, a sputtered-on layer, epitactically deposited phosphorus-doped silicon, or a phosphorus-enriched silicon nitride layer. Instead of the boron paste according to the invention mentioned in the figure, it is of course also possible to use a boron doping ink according to the invention.

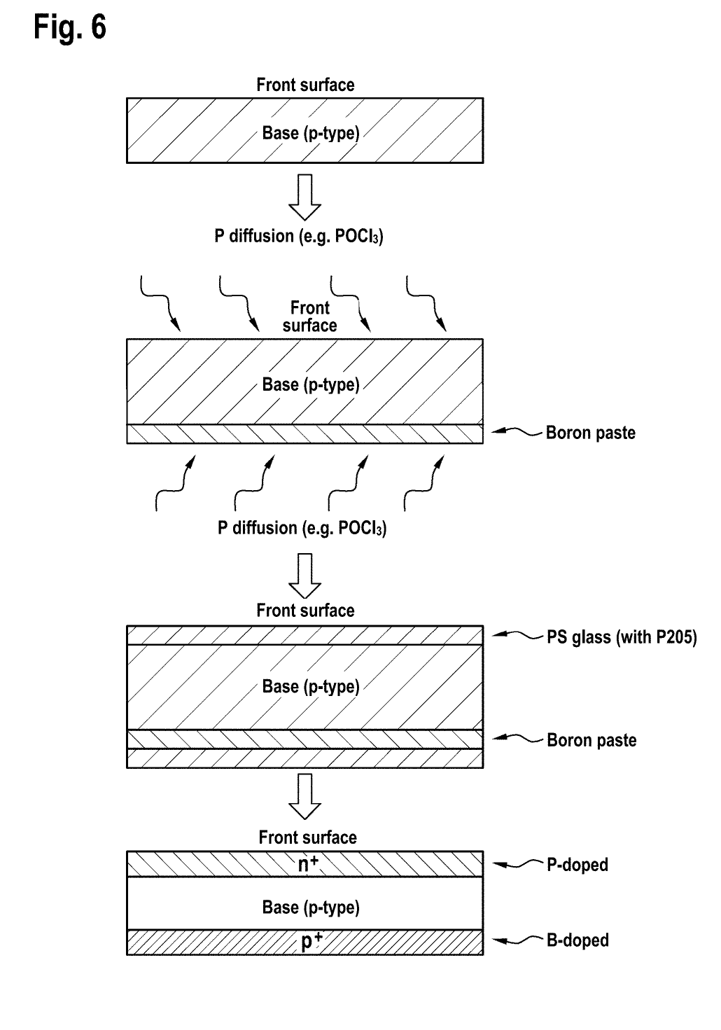

FIG. 6 shows a simplified process flow chart for the production of a possible bifacial (in this case p-type) solar cell (PERT structure). A co-diffusion process using classical diffusion with phosphoryl chloride is depicted. The hybrid sols and gels according to the invention (here only mentioned as boron paste), besides their function as dopant source, act as diffusion barrier against phosphorus diffusion.

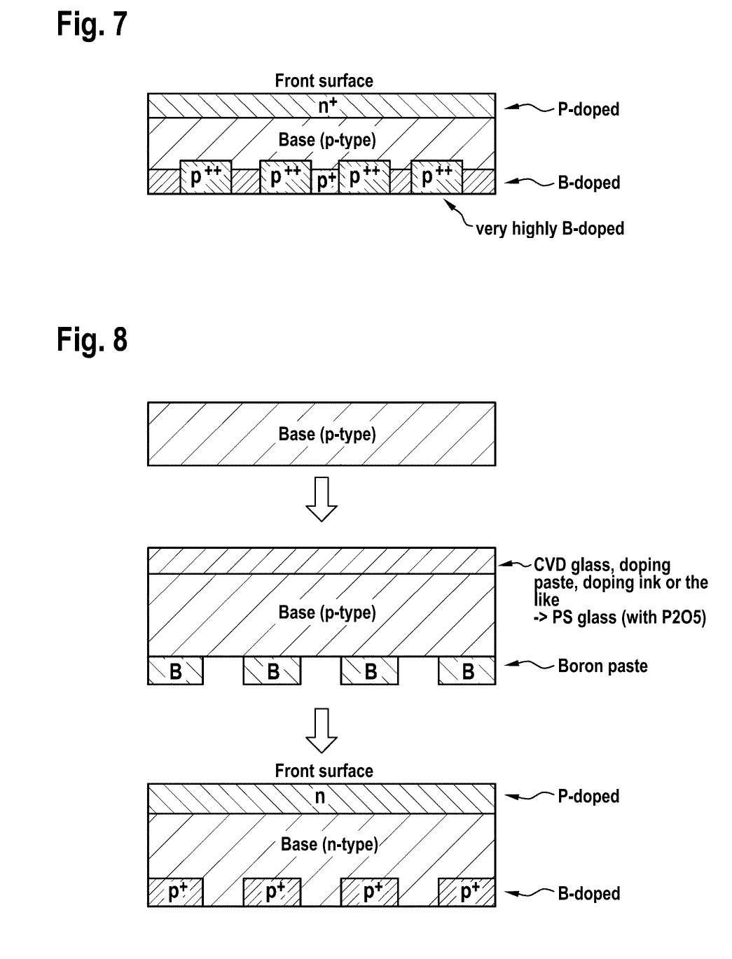

FIG. 7 shows a simplified diagrammatic representation of a possible bifacial solar cell (p-type) with selective or two-stage doping (selective back surface field) in the region of the boron back surface field.

FIG. 8 shows a possible process sequence for the production of a p-type PERL solar cell. The representation outlined in the scheme is based on the use of dopant sources which can be deposited over the entire surface and in a structured manner. In the case of the use of classical gas-phase diffusion, such as, for example, as a consequence of the use of phosphoryl chloride for phosphorus diffusion, an additional mask step for protection of the back-surface, open and base-doped regions of the wafer would also be necessary.

FIG. 8 shows a simplified diagrammatic representation of a possible production process of a p-type solar cell with back surface local contacts (PERL structure). The dopant source for the phosphorus diffusion was assumed to be a phosphorus paste, phosphorus ink or a CVD glass, but it can equally well be any other source deposited over the entire surface, such as, for example, a sputtered-on layer, epitactically deposited phosphorus-doped silicon, or a phosphorus-enriched silicon nitride layer. Instead of the boron paste according to the invention mentioned in the figure, it is of course also possible to use a boron doping ink according to the invention.

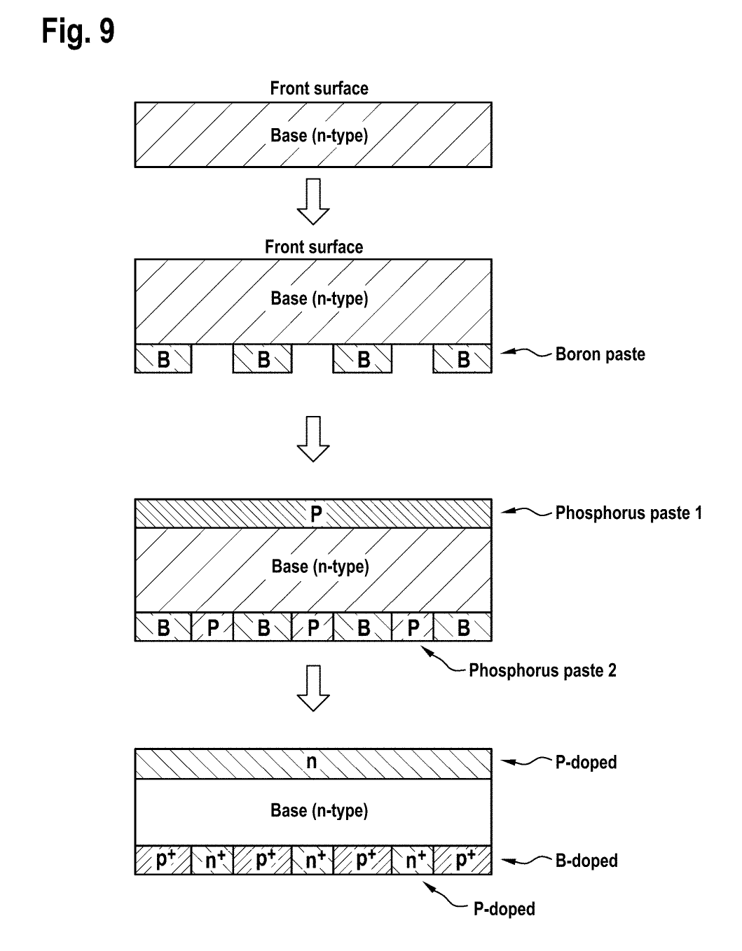

Let us now turn to the production of an IBC solar cell. With the classical procedure, based on gas-phase diffusion, we have seen that a sequence consisting of nine process steps is necessary in order to achieve the structured doping regions. FIG. 9 shows an alternative procedure which is based on the use of doping media to be applied in a structured manner to the back surface, such as the hybrid sols and gels according to the invention, while a further doping source can be applied over the entire surface to the front surface of the wafer. The doping source on the front side may likewise be, but does not necessarily have to be, a doping medium according to the invention, hybrid sol and/or hybrid gel. The alternative dopant sources already mentioned, such as, for example, a CVD glass, are likewise suitable. The above-mentioned naturally applies to the back surface. If the production process based on the hybrid sols and gels according to the invention is considered, five process steps are necessary in order to achieve a structured doping: deposition of source 1, deposition of source 2, deposition 3, high-temperature co-diffusion of all sources in a conventional tubular oven, removal of the dopant sources. This thus corresponds to a nominal reduction of the process steps necessary by 45% compared with the use of the classical diffusion process, which thus has the effect of significant advantages in the process costs. The same result is obtained on use of, for example, the deposition of CVD glasses as dopant source over the entire front surface. Since the use previously required deposition of the dopant source by a vacuum process, the achievable cost savings are not of the same order of magnitude as obtained in the case of the use of the printable hybrid sols and gels according to the invention as dopant source. If the CVD glasses having a doping action are also used for the definition of the doped regions present on the back surface, the requisite masking and structuring processes mean additional use of at least one structuring and etching step (previously counted as one unit); to this extent, the deposition of a further capping layer in between which separates two doped CVD glasses deposited one on top of the other can be omitted. Compared with the procedure based on gas-phase diffusion, a reduction of the process steps necessary by one third would thus be achieved. Compared with the use of the hybrid sols and gels according to the invention having a doping action, by contrast, additional use of a further process step or one fifth would arise. It goes without saying that a process sequence based on printing of the hybrid sols and gels according to the invention is preferable to the other process sequences outlined from the point of view of costs.

FIG. 9 shows a simplified diagrammatic representation of a possible production process of an n-type IBC solar cell. The dopant source for the front surface phosphorus diffusion was assumed to be a phosphorus paste, phosphorus ink or a CVD glass, but it can equally well be any other source deposited over the entire surface, such as, for example, a sputtered-on layer, epitactically deposited phosphorus-doped silicon or a phosphorus-enriched silicon nitride layer. On the back surface, the structured diffusion is obtained with the aid of various doping media, in this case referred to as boron and phosphorus paste. Instead of the boron paste according to the invention mentioned in the figure, it is of course entirely freely possible to use a boron doping ink according to the invention.

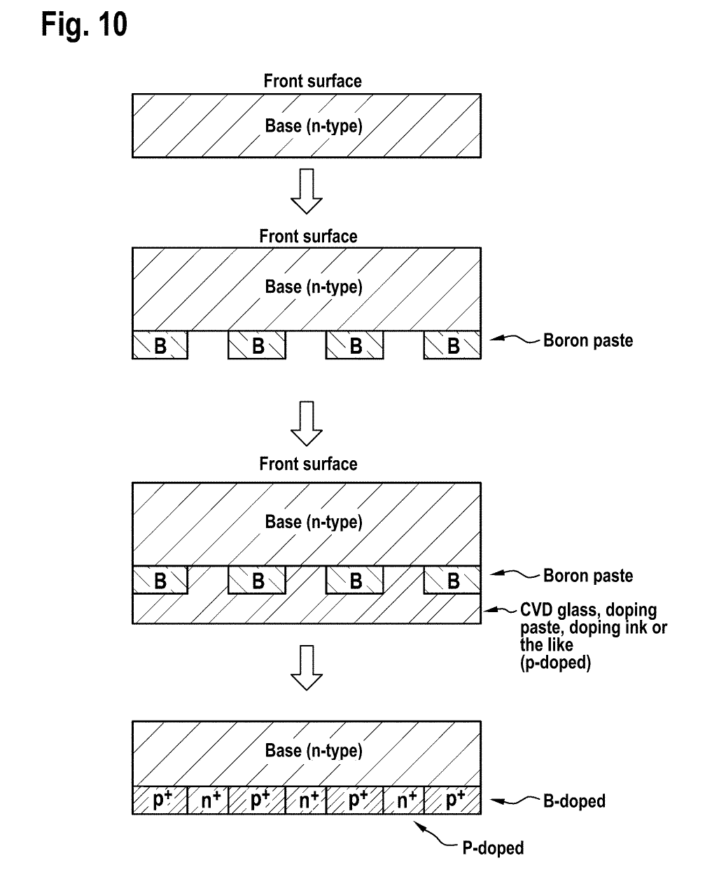

A further simplification of the production of IBC solar cells arises from the process flow chart depicted diagrammatically in FIG. 10. In this process flow chart, the property of the hybrid sols and gels according to the invention to act as diffusion barrier for phosphorus diffusion is utilised thoroughly. Consequently, as in the above-mentioned example, five process steps are used in order to achieve structured doping for IBC cells (in this case including the front surface doping, which is not depicted in the figure): deposition of source 01, deposition of source 2, deposition of source 3, high-temperature co-diffusion of all doping sources, removal of the dopant sources. In this example, a further cost reduction can be achieved compared with the example outlined above by depositing the back surface phosphorus source, for example, as doping ink using a very high-throughput deposition step. Such a step is, for example, the spray coating of the entire wafer surface. Alternatively, it may also be a flexographic printing step, which is claimed to have up to 2.5 to 3.0 times the wafer throughput compared with a conventional screen printing line. If the boron-containing doping source according to the invention is likewise deposited on the wafer surface, further cost reduction potentials can also be exploited compared with fairly inexpensive processing by screen printing.

FIG. 10 shows a simplified diagrammatic representation of a possible production process of an n-type IBC solar cell. Diffusion of the front surface was not considered in this case. The structured diffusion is achieved on the back surface with the aid of various doping media, in this case the structured application of the boron paste according to the invention, which can in principle equally well be a boron ink according to the invention. The back surface of the wafer is subsequently coated over the entire surface with a further phosphorus-containing dopant source, where the printed-on boron-containing doping medium according to the invention is likewise covered by the phosphorus-containing source. In the region not coated with the boron-containing medium according to the invention having a doping action, the phosphorus-containing source lies directly on the wafer surface and is able to dope this correspondingly with phosphorus during a high-temperature process, whereas in the regions of the boron-containing doping medium according to the invention, this acts as diffusion barrier against phosphorus diffusion and thus protects the wafer surface against penetration of phosphorus, but is at the same time capable of releasing the dopant, in this case boron, present in the medium to the wafer and thus inducing doping thereof with boron. Structured p/n junctions with an alternating sequence of the various doping regimes arise. The CVD doping glass mentioned in the figure can easily be replaced here by alternative dopant sources, such as, for example, a doping ink, a sputtered-on layer, epitactically deposited phosphorus-doped silicon, or a phosphorus-enriched silicon nitride layer.

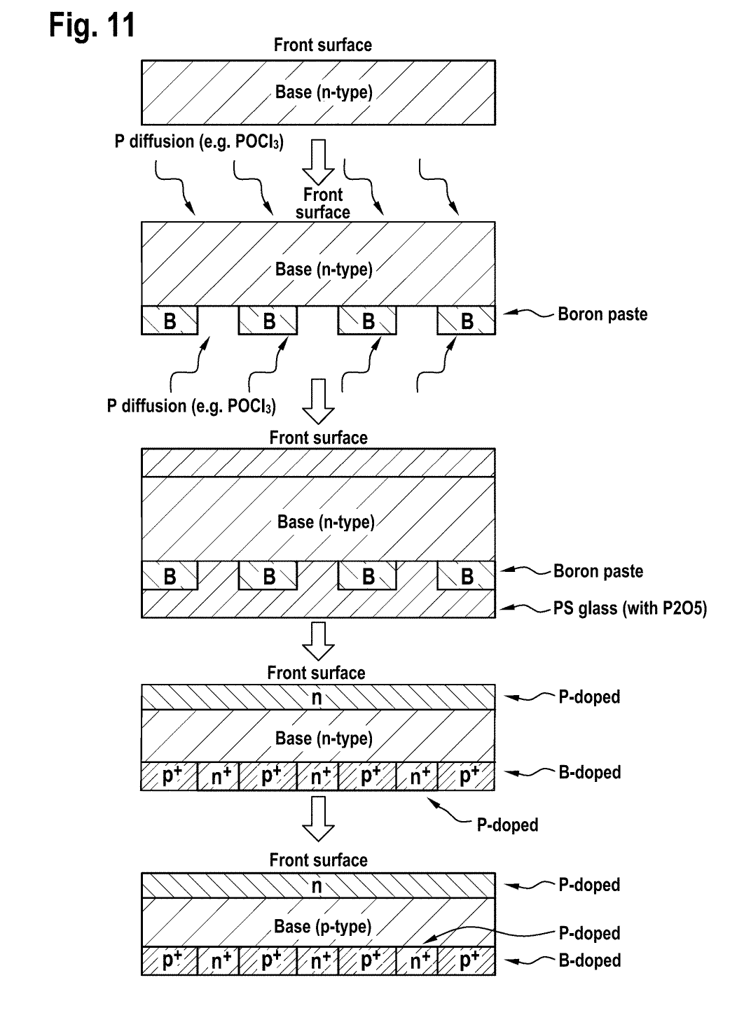

The production of an IBC solar cell can furthermore be simplified by rigorous utilisation of the diffusion barrier properties of the hybrid sols and gels according to the invention against phosphorus diffusion. In this simplification, use is made of a co-diffusion step for obtaining boron doping with simultaneous or consecutive diffusion with phosphorus owing to the, for example, thermal decomposition of phosphoryl chloride. Both features are carried out in a single process step in a conventional tubular oven process. The wafer is subsequently treated on the front surface by means of one-sided etching in such a way that the front surface doping is adjusted to a certain, desired measure of the sheet resistance (cf. FIG. 11). The latter is necessary since IBC solar cells generally have weaker doping on the front surface than at the back surface contact points, the local back surface field. Lower doping on the front surface promotes the passivation capacity of this surface, which is accompanied by a reduction in the dark current saturation density and thus an increase in the cell voltage. The latter is ultimately evident from an increase in efficiency or as one of the most important levers for influencing the efficiency of a solar cell, in this case positively. As a consequence, the following number of steps arises as a process chain for obtaining structured dopings: deposition of the boron source, high-temperature diffusion in the presence of a reactive phosphorus precursor, back-etching of the front surface doping and removal of the dopant sources. In summary, these are four process steps. If we now combine the etching of the front surface field and the removal of the glass as one process step, which could be regarded as justified inasmuch as this practice was likewise used in the listing of the requisite process steps in the course of the classical procedure for obtaining structured doping (cf. structuring and etching), but much more decisively since this process sequence already was or in part still is established in industrial manufacture in this form for the production of selective emitter solar cells, then in total three process steps arise. As a consequence, the production of IBC solar cells with the aid of the hybrid sols and gels according to the invention thus opens up the possibility of saving six process steps or two-thirds of the requisite effort compared with the classical, purely gas phase-promoted doping. In principle, the same process chain can also be achieved with alternative conventional PVD- or CVD-deposited dopant sources. However, these must be structured on the back surface after deposition in order to define regions which are to be doped by means of the gas-phase process—in this case practically likewise with the aid of phosphorus diffusion with phosphoryl chloride. The process chain arising from this thus necessarily has four process steps. Furthermore, a capping layer generally has to be incorporated in order to suppress penetration of the BSG glass applied in this case by the phosphorus diffusion with diffusing phosphorus. It thus becomes apparent that the use of the hybrid sols and gels according to the invention, which have a doping action and also act as barrier to phosphorus, has an inherent advantage which can significantly contribute to the cost-efficient production of IBC solar cells.

FIG. 11 shows a simplified diagrammatic representation of a possible production process of an n-type IBC solar cell. Diffusion of the front surface was considered in this case. On the back surface, the structured diffusion is achieved with the aid of various doping media, in this case the structured application of the boron paste according to the invention, where it can in principle equally well be a boron ink according to the invention. The wafer is subsequently subjected to conventional gas-phase diffusion with, for example, phosphoryl chloride as dopant precursor. All “open” points of the silicon wafer are thereby doped with phosphorus. The areas on the back surface which have been printed with the boron-containing dopant according to the invention are, owing to its property of acting as diffusion barrier against phosphorus diffusion, not doped with phosphorus, but instead by the boron present in the dopant source. The desired structured doping is consequently obtained on the back surface. The front surface may have been, but does not necessarily have to have been, subjected to excessive doping in the process. The doping intensity of the front surface is adjusted specifically against the desired requirements by controlled back-etching of the regions doped the most.

In the following examples, the preferred embodiments of the present invention are reproduced.

As stated above, the present description enables the person skilled in the art to use the invention comprehensively. Even without further comments, it will therefore be assumed that a person skilled in the art will be able to utilise the above description in the broadest scope.

Should anything be unclear, it goes without saying that the cited publications and patent literature should be consulted. Accordingly, these documents are regarded as part of the disclosure content of the present description. This applies in particular to the disclosure contents of the European patent applications with the file references 14004453.8 and 14004454.6 and the international application WO 2014/101990 A.

For better understanding and in order to illustrate the invention, examples are given below which are within the scope of protection of the present invention. These examples also serve to illustrate possible variants. Owing to the general validity of the inventive principle described, however, the examples are not suitable for reducing the scope of protection of the present invention to these alone.

Furthermore, it goes without saying to the person skilled in the art that, both in the examples given and also in the remainder of the description, the component amounts present in the compositions always only add up to 100% by weight, mol-% or vol.-%, based on the entire composition, and cannot exceed this, even if higher values could arise from the percent ranges indicated. Unless indicated otherwise, % data are therefore regarded as % by weight, mol-% or vol.-%.

The temperatures given in the examples and description and in the claims are always in ° C.

### EXAMPLES

### Example 1

55.2 g of ethylene glycol monobutyl ether (EGB) and 20.1 g of aluminium tri-sec-butylate (ASB) are initially introduced in a glass flask and stirred until a homogeneous mixture forms. 7.51 g of glacial acetic acid, 0.8 g of acetaldoxime and 0.49 g of acetylacetone are added to this mixture with stirring.

1.45 g of water, dissolved in 5 g of EGB, are subsequently added dropwise, and the mixture is refluxed at 80° C. for five hours. After warming, the mixture is subjected to a vacuum distillation at 70° C. until a final pressure of 30 mbar has been reached. The mass loss of readily volatile reaction products is 12.18 g. The distilled mixture is subsequently diluted with 62.3 g of Texanol and a further 65 g of EGB, and a mixed condensed sol consisting of precursors of boron oxide and silicon dioxide is added. The hybrid sol comprising silicon dioxide and boron oxide is to this end prepared as follows: 6.3 g of tetraacetoxy diborate are initially introduced in 40 g of benzyl benzoate, and 15 g of acetic anhydride are added. The mixture is warmed to 80° C. in an oil bath, and, when a clear solution has formed, 4.6 g of dimethyldimethoxysilane are added to this solution, and the entire mixture is left to react for 45 minutes with stirring. The hybrid sol is subsequently likewise subjected to a vacuum distillation at 70° C. until a final pressure of 30 mbar has been reached, where the mass loss of readily volatile reaction products is 7.89 g. 9 g of Synchro wax are added to the entire 110 g of mixture, and the mixture is warmed at 150° C. with stirring until everything has dissolved and the mixture is clear. The mixture is subsequently allowed to cool with vigorous stirring. A pseudoplastic and very readily printable paste forms.

### Example 2

The paste according to Example 1 is printed onto a wafer with the aid of a conventional screen-printing machine and a 350 mesh screen with a wire thickness of 16 μm (stainless steel) and an emulsion thickness of 8-12 μm using a doctor-blade speed of 170 mm/s and a doctor-blade pressure of 1 bar and subsequently subjected to drying in a through-flow oven. The heating zones in the through-flow oven are for this purpose set to 350/350/375/375/375/400/400° C.

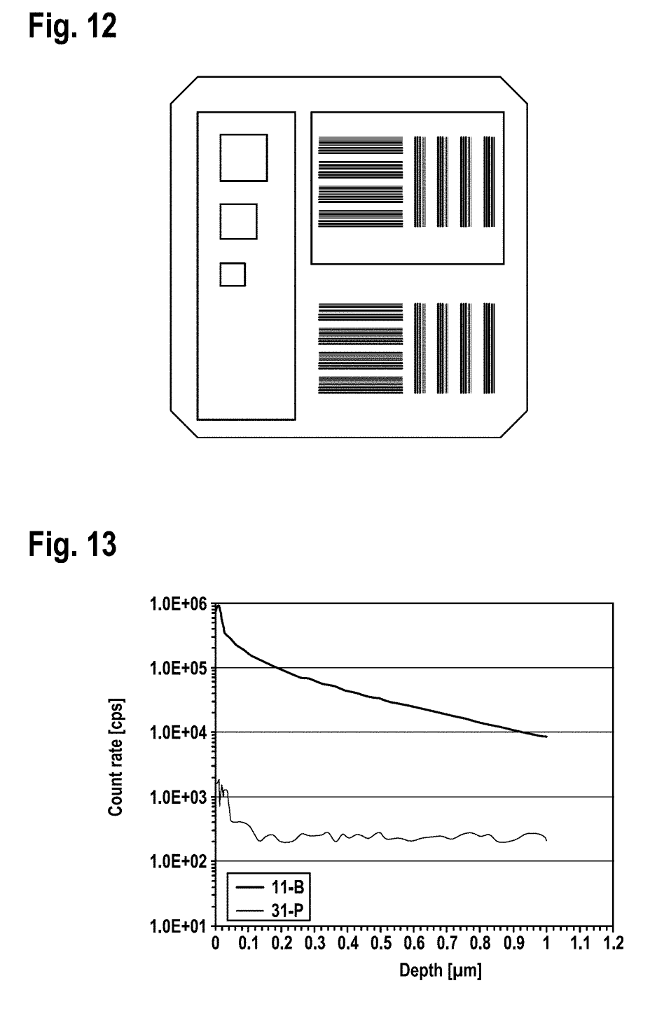

FIG. 12 shows a silicon wafer printed with the aid of the hybrid gel according to the invention in accordance with the composition and preparation of Example 1 after drying in a through-flow oven.

### Example 4

The paste according to Example 1 is printed over a large area onto a rough CZ wafer surface (n-type) with the aid of a conventional screen-printing machine and a 280 mesh screen with a wire thickness of 25 μm (stainless steel). The wet application rate is 1.5 mg/cm². The printed wafer is subsequently dried at 300° C. on a conventional laboratory hotplate for 3 minutes and subsequently subjected to a diffusion process. To this end, the wafer is introduced into a diffusion oven at approximately 700° C., and the oven is subsequently heated to a diffusion temperature of 950° C. The wafer is kept at this plateau temperature for 30 minutes in a nitrogen atmosphere comprising 0.2% v/v of oxygen. After the boron diffusion, the wafer is subjected to phosphorus diffusion with phosphoryl chloride at low temperature, 880° C., in the same process tube. After the diffusions and cooling of the wafer, the latter is freed from glasses present on the wafer surfaces by means of etching with dilute hydrofluoric acid. The region which had previously been printed with the boron paste according to the invention has a hydrophilic wetting behaviour on rinsing of the wafer surface with water, which represents a clear indication of the presence of a boron skin in this region. The sheet resistance determined in the surface region printed with the boron paste is 195 Ω/sqr (p-type doping). The regions not protected by the boron paste have a sheet resistance of 90 Ω/sqr (n-type doping). The SIMS (secondary ion mass spectrometry) depth profile of the dopants is determined in the region of the surface which was printed by means of the boron paste according to the invention. In the region covered with the B paste, boron doping extending from the wafer surface into that of the silicon is determined, apart from the n-type base doping. The printed-on paste layer thus acts as diffusion barrier against typical phosphorus diffusion.

FIG. 13 shows the SIMS profile of a rough silicon surface which has been printed with the boron paste according to the invention and subsequently subjected to gas-phase diffusion with phosphoryl chloride. Owing to the rough surface, only relative concentrations in the form of count rates can be obtained.

### Example 4

3.66 g of boric acid which has been pre-dried in a desiccator are dissolved in 40 g of dibenzyl ether, 8 g of acetic anhydride and 8 g of tetraethyl orthosilicate in a round-bottomed flask at 100° C. with stirring and left to react for 30 minutes. 60 g of ethylene glycol monobutyl ether are subsequently dissolved in a solution of 0.4 g of 1,3-cyclohexanedione and 7.2 g of salicylic acid, and 160 g of ethanol are added. When the reaction mixture has mixed completely, 20 g of aluminium tri-sec-butylate are added to this solution. The solution is refluxed for a further hour. The boron ink is subsequently filtered through a filter having a pore size of 0.45 μm and deaerated. For printing by means of an ink-jet printer, the ink is introduced into a suitable print head, Spectra SE128AA, and printed onto silicon wafers which have been subjected to acidic polish-etching with selection of the following printing conditions: firing frequency—1500 Hz; voltage—70 V; trapezium function—1-11—1 μs; reduced-pressure difference above the ink tank—21.5 mbar. The substrates are warmed from below on the substrate holder. The respective warming (→printing temperature) is mentioned in the examples given. Squares having an edge length of 2 cm each are printed onto the wafers. The selected print resolution is likewise reproduced in the individual examples. After the printing, the printed wafers are dried at temperatures between 400° C. and 600° C. on a conventional laboratory hotplate for five to ten minutes in each case. The dried structures are subsequently printed with a phosphorus ink, in accordance with the composition as mentioned in the patent application WO 2014/101990, likewise by means of ink-jet printing. The respective print resolution, and also the respective printing temperature, is reproduced in the examples. The phosphorus ink is processed with selection of the following printing conditions: firing frequency—1500 Hz; voltage—90 V; trapezium function—1-11—1 μs; reduced-pressure difference above the ink tank—21.5 mbar. The printed structure likewise consists of a square having an edge length of 2 cm each which has been deposited on the square with the boron ink. After the printing, the phosphorus ink is dried at temperatures between 400° C. and 600° C. on a conventional laboratory hotplate for five to ten minutes in each case. The entire structure is subsequently subjected to high-temperature diffusion in a tubular oven at 950° C. To this end, the diffusion is carried out for 30 minutes in a stream of nitrogen, followed by an oxidation process for five minutes in an atmosphere comprising nitrogen and oxygen (20% v/v) and furthermore followed by a drive-in phase of ten minutes in a nitrogen atmosphere. The diffused wafers are subsequently freed from the printed-on dopant sources by means of etching in dilute hydrofluoric acid, and the doping profile is measured in the printed areas with the aid of electrochemical capacitance-voltage measurement (ECV).

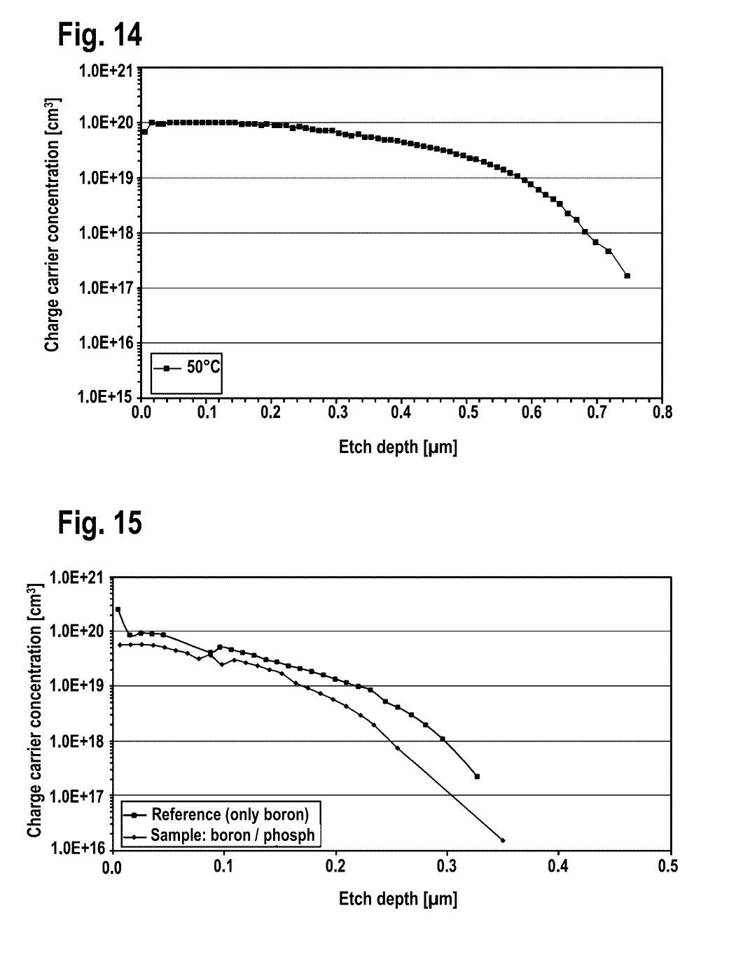

FIG. 14 shows the ECV profile of a silicon wafer which has been printed with the boron ink according to the invention, subsequently overcoated with phosphorus ink and brought to diffusion. The profile shows the boron doping arising on use of a print resolution of 508 dpi and a printing temperature of 50° C. No phosphorus doping was measured in the profile, for example change of the charge carrier type in different regions of the profile.

TABLE 1
Temperatures and print resolutions for the overcoating
experiments described above with the boron ink according
to the invention by means of a phosphorus ink likewise
printed by means of ink-jet printing. Analysis of the
printed and doped sandwich structures in all cases
resulted in boron doping achieved in the silicon wafer.

| | Temperature | 40 | | 50 |
|---|---|---|---|---|
| | [° C.] Boron | | | |
| | Print resolution | | | |
| | [dpi]: [symbol] | 400 | 450 | 400 |
| Temperature | Boron | | | |
| [° C.] | Phosphorus | | | |
| Phosphorus | [symbol] | | | |
| 50 | 508 | B | B | B |
| 40 | 508 | B | B | B |
| 40 | 450 | B | B | B |
| 40 | 400 | B | B | B |
| 40 | 350 | B | B | B |
| 40 | 300 | B | B | B |
| 40 | 250 | B | B | B |
| 40 | 200 | B | B | B |

### Example 5

2 g of boron oxide are dissolved in 10.5 g of tetrahydrofuran, 3 g of acetic anhydride and 4 g of tetraethyl orthosilicate in a round-bottomed flask with stirring and refluxing and left to react for 30 minutes. 41 g of ethylene glycol monobutyl ether, in which 2 g of salicylic acid and 0.6 g of acetylacetone have been pre-dissolved, and 20 g of diethylene glycol monoethyl ether are subsequently added. When the reaction mixture has mixed completely, 10 g of aluminium tri-sec-butylate are added to this solution. The solution is refluxed for a further hour, and readily volatile solvents and reaction products are subsequently stripped off in a rotary evaporator at 60° C. with achievement of a final pressure of 50 mbar. The boron ink is subsequently filtered through a filter having a pore size of 0.45 μm and deaerated. p-type test wafers which have been polished on one side are subsequently coated by means of the spin-coating process using a two-step coating programme: spinning for 15 s at 500 rpm in order to distribute the ink, followed by 2,000 rpm for 45 s. The coated wafers are subsequently dried at 500° C. on a conventional laboratory hotplate for five minutes. After this coating, the wafers are re-coated on the side already coated with boron ink with a phosphorus-containing doping ink, in accordance with the composition as mentioned in the patent application WO 2014/101990, with the aid of the same spinning programme, after which the wafers are likewise dried at 500° C. for five minutes. The double-coated wafers are brought to diffusion in a tubular oven at 930° C. in a stream of nitrogen for 30 minutes. After the diffusion, the residues of the doping media are removed from the surface with the aid of dilute hydrofluoric acid, and the wafers are tested with respect to their respective doping profiles with the aid of electrochemical capacitance-voltage measurement (ECV) and secondary ion mass spectrometry (SIMS).

The boron ink is impermeable to diffusion of phosphorus from the phosphorus ink.

FIG. 15 shows the ECV profile of a silicon wafer which has been coated with the boron ink according to the invention, subsequently overcoated with phosphorus ink and brought to diffusion. No phosphorus doping was measured in the profile, for example change of the charge carrier type in different regions of the profile. For comparison, an ECV profile of a reference sample which has been treated in the same way is depicted.

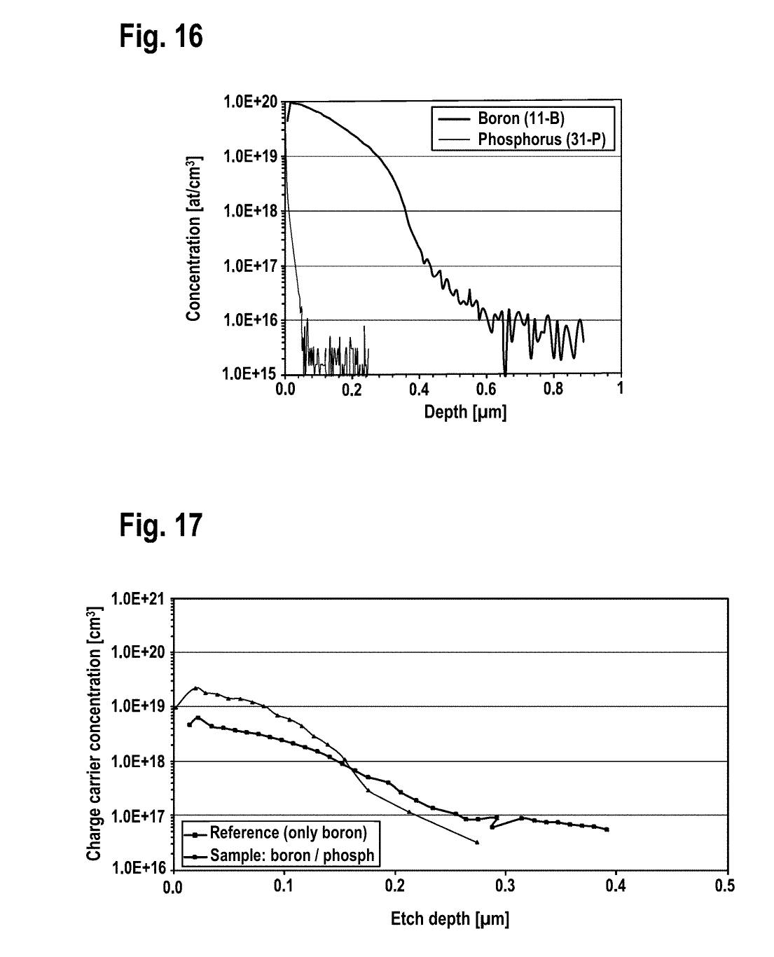

FIG. 16 shows the SIMS profile of a sample comparable to FIG. 14. The SIMS profile shows the changes in concentration of boron and phosphorus in silicon. The phosphorus profile reaches a concentration of 1*10¹⁶ atoms/cm³ after a depth of 40 nm.

In a comparative experiment, a boron ink, exclusively based on a hybrid sol consisting of precursors of silicon dioxide and boron oxide, is prepared in accordance with the procedure mentioned above. The aluminium oxide component is replaced here by silicon dioxide. The ink is applied by means of spin coating using the coating programme already mentioned and subsequently likewise overcoated with phosphorus ink. The double-coated samples are subjected to the diffusion already described and subsequently analysed in the same way.

FIG. 17 shows the ECV profile of a silicon wafer which has been coated with a boron ink which is not according to the invention, subsequently overcoated with phosphorus ink and brought to diffusion. Exclusively phosphorus doping (blue) was measured in the profile. For comparison, an ECV profile of a reference sample which has been treated in the same way is depicted.

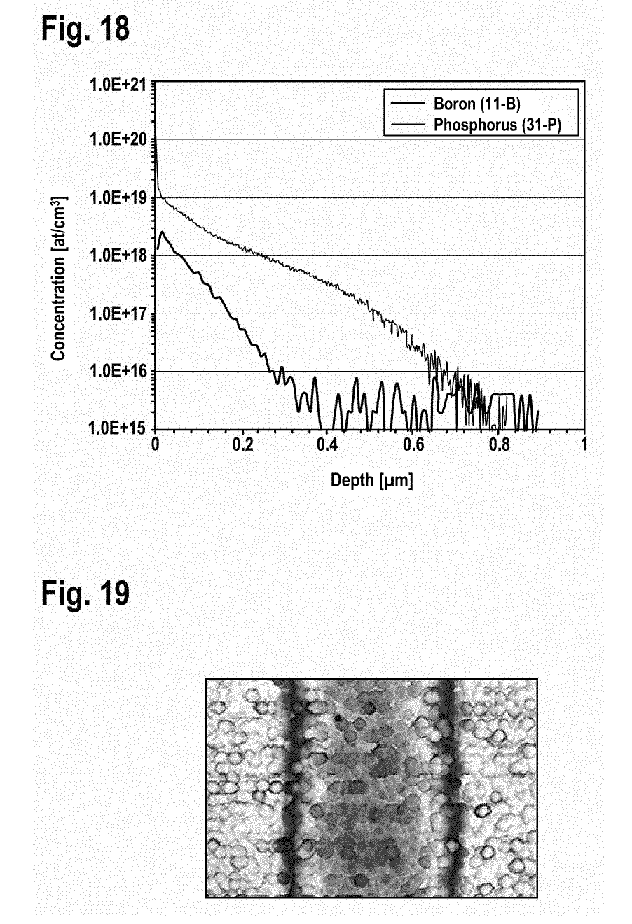

FIG. 18 shows the SIMS profile of a sample comparable to FIG. 16. The SIMS profile shows the changes in concentration of boron and phosphorus in silicon. The concentration prevailing in the silicon was phosphorus.

The hybrid sol on the basis of silicon dioxide and boron oxide and simultaneous absence of aluminium oxide was not impermeable to diffusion of phosphorus from the phosphorus ink.

### Example 6

72.2 g of ethylene glycol monobutyl ether (EGB), 2.9 g of dimethyldimethoxysilane and 12.8 g of aluminium tri-sec-butylate (ASB) are initially introduced in a glass flask and stirred until a homogeneous mixture forms. 12.2 g of glacial acetic acid and 0.38 g of acetaldoxime are added to this mixture in the said sequence with stirring. 1.9 g of water, dissolved in 5 g of EGB, are subsequently added dropwise, and the mixture is refluxed at 80° C. for four hours. After the warming, the hybrid sol is subjected to vacuum distillation at 70° C. for two hours until a final pressure of 20 mbar has been reached. The mass loss of readily volatile reaction products is 15.3 g. 84 g of α-terpineol (isomer mixture) and 3.76 g of tetraacetoxy diborate are subsequently added to the distilled mixture and mixed intensively. A pseudoplastic and very readily printable, transparent paste forms. The viscosity of the paste is 8.5 Pa*s at a shear rate of 25 1/s and a temperature of 23° C.

The paste is printed with the aid of a screen printer using a trampoline screen with stainless-steel fabric (400 mesh, 18 μm wire diameter, calendered, 8-12 μm emulsion on top of the fabric) onto wafers which have been subjected to alkaline polish-polishing, using the following printing parameters:

a screen separation of 2 mm, a printing speed of 200 mm/s, a flooding speed of likewise 200 mm/s, a doctor-blade pressure of 60 N during the printing operation and a doctor-blade pressure of 20 N during the flooding, and using a carbon fibre doctor blade with polyurethane rubber of Shore hardness of 65°

The printed wafers are subsequently dried in a through-flow oven warmed to 400° C. The belt speed is 90 cm/s. The length of the heating zones is 3 m. The paste transfer rate is 0.93 mg/cm².

FIG. 19 shows a photomicrograph of a line screen-printed with a doping paste according to Example 6 and dried.

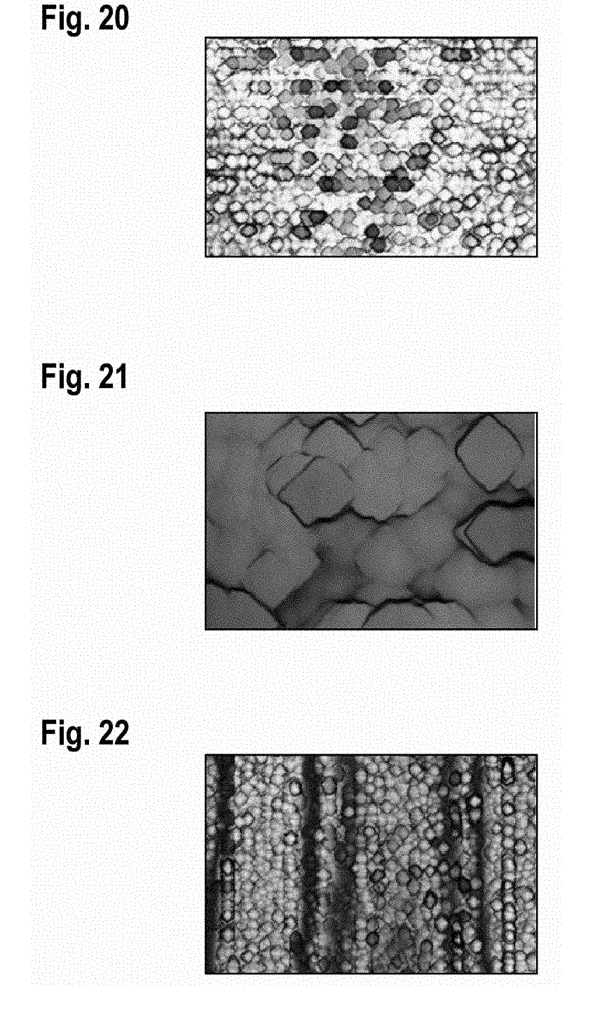

FIG. 20 shows a photomicrograph of a paste area screen-printed with a doping paste according to Example 6 and dried.

FIG. 21 shows a photomicrograph of a paste area screen-printed with a doping paste according to Example 6 and dried.

### Example 7

72.3 g of ethylene glycol monobutyl ether (EGB), 2.8 g of dimethyldimethoxysilane and 12.9 g of aluminium tri-sec-butylate (ASB) are initially introduced in a glass flask and stirred until a homogeneous mixture forms. 12.1 g of glacial acetic acid and 1.5 g of acetaldoxime are added to this mixture in the said sequence with stirring. 1.9 g of water, dissolved in 5 g of EGB, are subsequently added dropwise, and the mixture is refluxed at 80° C. for four hours. After the warming, the hybrid sol is subjected to vacuum distillation at 70° C. for two hours until a final pressure of 20 mbar has been reached. The mass loss of readily volatile reaction products is 15.3 g. 84 g of α-terpineol (isomer mixture) and 3.8 g of tetraacetoxy diborate are subsequently added to the distilled mixture and mixed intensively. A pseudoplastic and very readily printable, transparent paste forms. The viscosity of the paste is 6.7 Pa*s at a shear rate of 25 1/s and a temperature of 23° C. The paste is printed with the aid of a screen printer using a trampoline screen with stainless-steel fabric (400 mesh, 18 μm wire diameter, calendered, 8-12 μm emulsion on top of the fabric) onto wafers which have been subjected to alkaline polish-etching, using the following printing parameters: a screen separation of 2 mm, a printing speed of 200 mm/s, a flooding speed of likewise 200 mm/s, a doctor-blade pressure of 60 N during the printing operation and a doctor-blade pressure of 20 N during the flooding, and using a carbon fibre doctor blade with polyurethane rubber having a Shore hardness of 65°. The printed wafers are subsequently dried in a through-flow oven warmed to 400° C. The belt speed is 90 cm/s. The length of the heating zones is 3 m. The paste transfer rate is 1.04 mg/cm².

FIG. 22: Photomicrograph of a line which has been screen-printed with a doping paste according to Example 7 and dried.

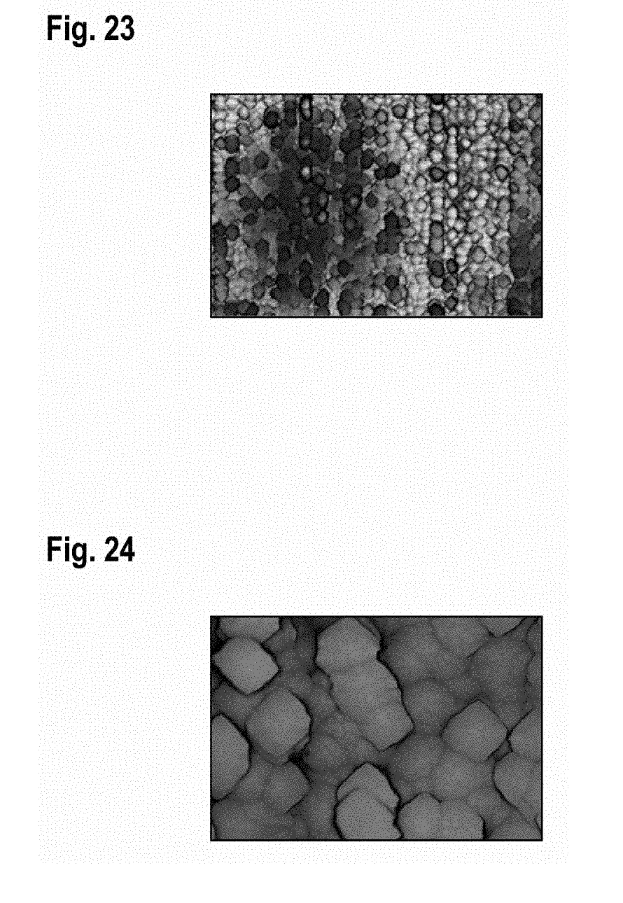

FIG. 23: Photomicrograph of a paste area which has been screen-printed with a doping paste according to Example 7 and dried.

FIG. 24: Photomicrograph of a paste area which has been screen-printed with a doping paste according to Example 7 and dried.

In a further procedure, both CZ n-type silicon wafers which have been subjected to alkaline polish-etching and also those which have been alkaline-textured and subsequently polished by means of acidic etches on one side are printed with the doping paste approximately over the entire surface (˜93%). The printing is carried out using a screen with stainless-steel fabric (400/18, 10 μm emulsion thickness over the fabric). The paste application rate is 0.9 mg/cm². The wafers are dried at 400° C. on a hotplate for three minutes and subsequently subjected to co-diffusion at a plateau temperature of 950° C. for 30 minutes. During the co-diffusion, the wafer is diffused and doped with boron on the side printed with the boron paste, whereas the wafer side or surface that is not printed with boron paste is diffused and doped with phosphorus. The phosphorus diffusion is in this case achieved with the aid of phosphoryl chloride vapour, which is introduced into the hot oven atmosphere transported by a stream of inert gas. As a consequence of the high temperature prevailing in the oven and the oxygen simultaneously present in the oven atmosphere, the phosphoryl chloride is combusted to give phosphorus pentoxide. The phosphorus pentoxide precipitates in combination with a silicon dioxide forming on the wafer surface owing to the oxygen present in the oven atmosphere. The mixture of the silicon dioxide with the phosphorus pentoxide is also referred to as PSG glass. The doping of the silicon wafer takes place from the PSG glass on the surface. On surface regions on which boron paste is already present, a PSG glass can only form on the surface of the boron paste. If the boron paste acts as diffusion barrier against phosphorus, phosphorus diffusion cannot take place at points at which boron paste is already present, but instead only diffusion of boron itself which diffuses out of the paste layer into the silicon wafer. This type of co-diffusion can be carried out in various embodiments. In principle, the phosphoryl chloride can be combusted in the oven at the beginning of the diffusion process. The beginning of the process in the industrial production of solar cells is generally taken to mean a temperature range between 600° C. and 800° C., in which the wafers to be diffused can be introduced into the diffusion oven. Furthermore, combustion can take place in the oven cavity during heating of the oven to the desired process temperature. Phosphoryl chloride can accordingly also be introduced into the oven during holding of the plateau temperature, and also during cooling of the oven or perhaps also after a second plateau temperature, which may be higher and/or also lower than the first plateau temperature, has been reached. Of the above-mentioned possibilities, any desired combinations of the phases of possible introduction of phosphoryl chloride into the diffusion oven can also be carried out, depending on the respective requirements. Some of these possibilities have been sketched. In this figure, the possibility of use of a second plateau temperature is not depicted.

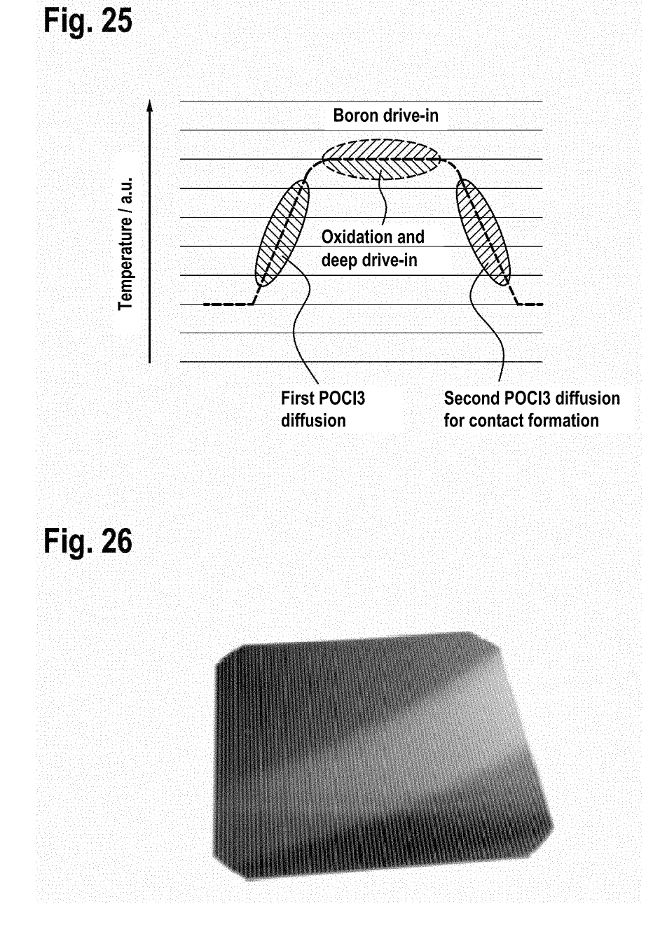

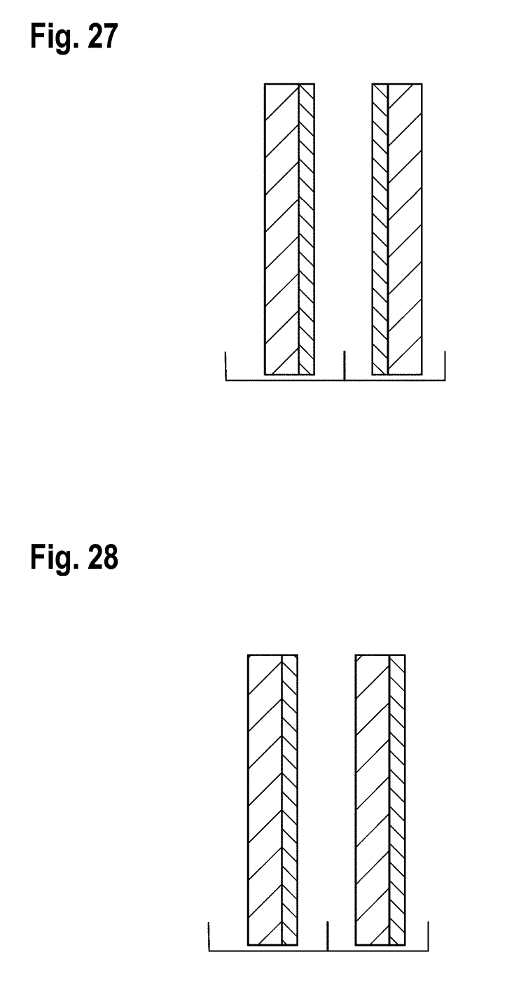

The wafers printed with the boron paste are subjected to a co-diffusion process, as depicted in FIG. 25, in which the phosphoryl chloride is introduced into the diffusion oven before the plateau temperature which is necessary in order to achieve boron diffusion, in this case 950° C., has been reached. During the diffusion, the wafers are arranged in pairs in the process boat in such a way that their sides printed with boron paste in each case face one another (cf. FIG. 27). In each case, a wafer is accommodated in a slot of the process boat. The nominal separation between the substrates is thus about 2.5 mm. After the diffusion, the wafers are subjected to a glass etch in dilute hydrofluoric acid and their sheet resistances are subsequently measured by means of four-point measurement. The side of the wafer diffused with the boron paste has a sheet resistance of 35Ω/□ (range: 10Ω/□, whereas the opposite side of the wafer printed with the boron paste, has a sheet resistance of 70Ω/□. With the aid of a p/n tester, it is demonstrated that the side that has a sheet resistance of 35Ω/□ is exclusively p-doped, i.e. doped with boron, while the opposite side, which has a sheet resistance of 70Ω/□, is exclusively n-doped, i.e. doped with phosphorus. There is no fundamental difference between the sheet resistances on the wafers subjected to alkaline polish-etching and those in which the alkaline texture has been subjected to subsequent acidic polishing on one side—both on the wafer side doped with phosphorus and also on the wafer side doped with boron.

In a further, identical embodiment of the co-diffusion experiment outlined above, the wafers are arranged in the process boat for diffusion in such a way that the wafer side printed with the boron paste is opposite an unprinted wafer surface (cf. FIG. 28). After the post-diffusive aftertreatment of the wafers already outlined above, the sheet resistances and also the prevailing dopings are determined using the methods already mentioned. A sheet resistance of 37Ω/□ (range: 10Ω/□) is determined on the side printed with boron paste. This side is exclusively p-doped, while a sheet resistance of 70Ω/□ is measured on the back surface. The back surface is exclusively n-doped.

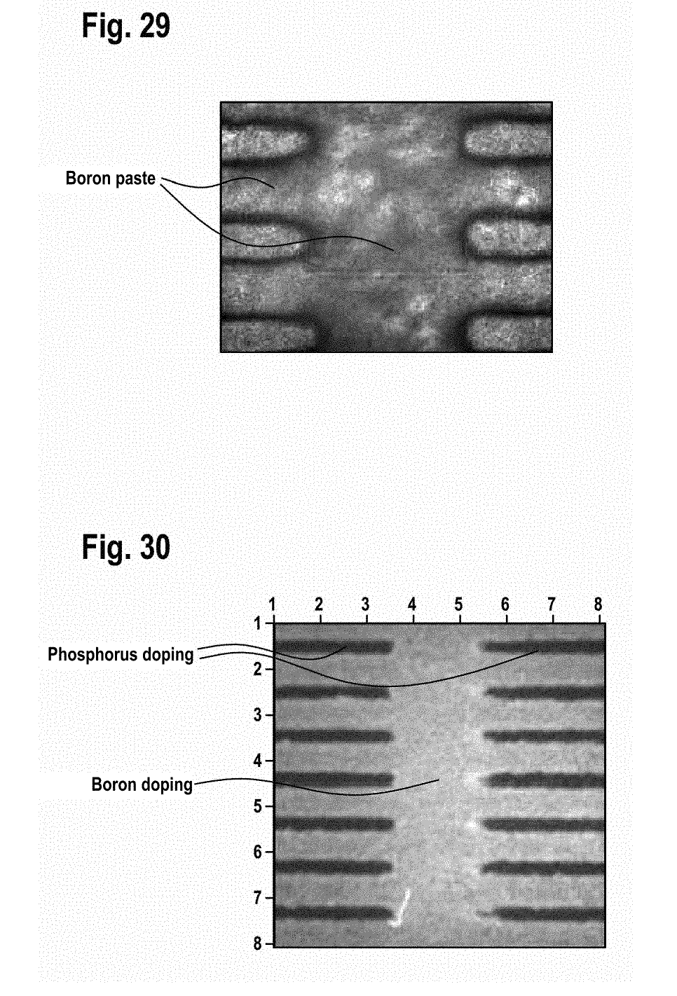

In a further embodiment of the co-diffusion experiment already described, wafers are printed with the boron paste according to the invention with a paste application rate of 0.7 mg/cm² and subjected to the same diffusion conditions. The arrangement of the wafers in the process boat was carried out in accordance with FIG. 29. After processing of the diffused wafers in accordance with the procedure already outlined, a sheet resistance of 37Ω/□ (range: 8Ω/□) can be determined on the side printed with the boron paste. The doping prevailing on this wafer surface is p-type.

In a further embodiment of the co-diffusion experiment, wafers are printed with the boron paste according to the invention with a paste application rate of 0.9 mg/cm². The printed wafers are dried at 400° C. on a hotplate for three minutes and subsequently in a through-flow oven for a further 20 minutes. The wafers are subjected to a co-diffusion experiment already described above, where the wafer surfaces printed with boron paste are in each case arranged opposite one another.

After the diffusion, the wafers are treated further in the usual manner, and the sheet resistance on the side printed with the paste is subsequently determined by means of four-point measurement. The sheet resistance is 41Ω/□ (range: 5Ω/□). The most intensive drying of the paste results in a significant reduction in the variance of the sheet resistance.

In a further embodiment of the co-diffusion, wafers are printed with a screen using a structured screen layout. The screen used corresponds to the characteristics already mentioned above. Furthermore, the screen has a busbar to be printed centrally onto the wafer surface, from which bars or fingers with a width of 700 μm each branch off both to the right and also to the left.

Lands with a width of 300 μm, which protect the wafer surface against the paste print, are located between the bars. The wafers printed in this way are dried at 400° C. on a hotplate for three minutes, subsequently aligned in the process boat in an arrangement in accordance with FIG. 28 and brought to diffusion using the co-diffusion conditions already described. After the further treatment of the diffused wafers, which has already been described above, these are investigated by means of an imaging process in order to determine the sheet resistance (sheet resistance imaging). The measurement method used was carried out without calibration, which means that the sheet resistance information is coded via the signals and signal changes obtained by the measurement method (in this case count rates of the IR radiation detected with the aid of the process). FIG. 29 shows a photomicrograph of a printed structure after the co-diffusion. The boron paste is still present on the sample. The regions printed with the boron paste have a dark-blue colour. A wafer which has been printed with the boron paste according to the invention and dried is depicted: the structure shown in this figure corresponds in principle to the structuring described above, apart from the fact that the busbar arranged centrally is not present on this wafer surface and the dimensions of the printed bars do not correspond exactly to the dimensions likewise already mentioned. The structures evident from FIG. 29 are transferred to the sheet resistance mapping shown in FIG. 30. The regions depicted in orange-red in FIG. 30 correspond to the structures printed with the boron paste, while the red regions can be assigned to the recesses in the structure which have been diffused with phosphorus as a consequence of the co-diffusion. In addition, it is evident that the adjacent regions have a very sharp delimitation and a very well-defined transition region, with the measurement accuracy of the means available and taking into account the measured wafer surfaces (scattering of the signal). FIG. 30 shows sharply delimited p/n junctions, alternating in accordance with the performance of the experiments, which can be produced with the aid of a single high-temperature diffusion step.

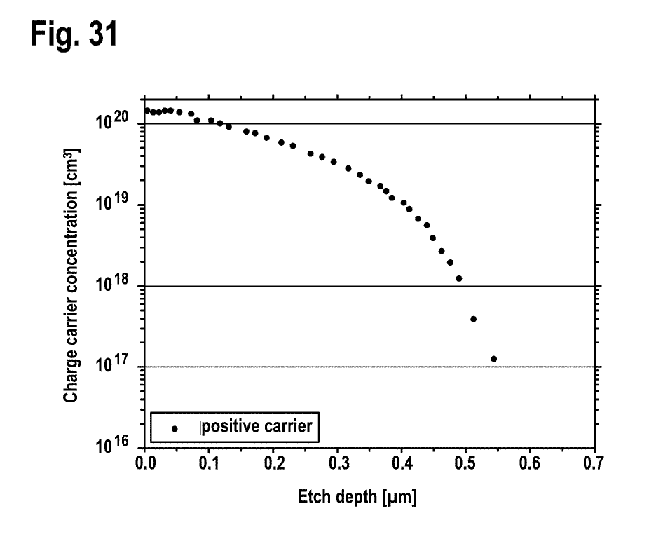

Furthermore, an ECV profile (electrochemical capacitance/voltage profiling) of the busbar region produced with the aid of the boron paste according to the invention and shown in FIG. 29 and also in FIG. 30 is depicted in FIG. 31. The profile shows an emitter profile having a depth of the p/n junction of about 600 nm. Exclusively p-type doping prevails. The surface concentration of the charge carriers (holes) of the emitter profile is about 2*10²⁰ cm⁻³. Through suitable manipulation of the process procedure of the co-diffusion process, both the depth of the profile and also the surface concentration can be adjusted in the desired manner (for example through the choice of the diffusion temperature, the diffusion length, the composition of the gas atmosphere used during the diffusion process, and here in particular by setting a determined oxygen concentration).

FIG. 25 shows a photomicrograph of a line which has been screen-printed with a doping paste according to Example 7 and dried.

FIG. 26 shows the photograph of a monocrystalline silicon wafer printed with boron paste according to Example 7 in the form of a bar structure.

FIG. 27 shows an arrangement of wafers in a process boat during a co-diffusion process. The wafer surfaces printed with boron paste are opposite one another.

FIG. 28 shows an arrangement of wafers in a process boat during a co-diffusion process. The wafer surfaces printed with boron paste are opposite one another.

FIG. 29 shows a photomicrograph of a wafer printed with the boron paste according to the invention (alkaline-textured wafer surface subjected to acidic post-polishing on one side). The nominal dimensions of the printed-on structure are mentioned in the text.

FIG. 30 shows a sheet resistance mapping with the aid of the SRI process. The orange-yellow regions correspond to boron doping, whereas the red regions can be assigned to phosphorus doping. The structure shown corresponds to that depicted in FIG. 29.

FIG. 31 shows an ECV profile of an emitter profile (boron, p-type) obtained by means of the boron paste according to the invention and using a co-diffusion process. The depth of the p/n junction is about 600 nm. The surface concentration of the charge carriers (holes) is about 2*10²⁰ cm⁻³.

### Example 8

563.2 g of ethylene glycol monobutyl ether (EGB), 23 g of dimethyldimethoxysilane and 102.2 g of aluminium tri-sec-butylate (ASB) are initially introduced in a glass flask and stirred until a homogeneous mixture forms. 97.8 g of glacial acetic acid and 6 g of acetaldoxime are added to this mixture in the said sequence with stirring. 15.6 g of water, dissolved in 50 g of EGB, are subsequently added dropwise, and the mixture is refluxed at 80° C. for four hours. After the warming, the hybrid sol is subjected to vacuum distillation at 70° C. for two hours until a final pressure of 20 mbar has been reached. The mass loss of readily volatile reaction products is 119.6 g. 782 g of α-terpineol (isomer mixture) and 32.2 g of tetraacetoxy diborate are subsequently added to the distilled mixture and mixed intensively. A pseudoplastic and very readily printable, transparent paste forms. The viscosity of the paste is 7.5 Pa*s at a shear rate of 25 1/s and a temperature of 23° C.

The paste is printed with the aid of a screen printer using a trampoline screen with stainless-steel fabric (400 mesh, 18 μm wire diameter, calendered, 8-12 μm emulsion on top of the fabric) onto wafers which have been subjected to alkaline polish-etching, using the following printing parameters:

a screen separation of 2 mm,
a printing speed of 200 mm/s,
a flooding speed of likewise 200 mm/s,
a doctor-blade pressure of 60 N during the printing operation and a doctor-blade pressure of 20 N during the flooding, and using a carbon fibre doctor blade with polyurethane rubber having a Shore hardness of 65°.

The printed wafers are subsequently dried in a through-flow oven warmed to 400° C. The belt speed is 90 cm/s. The length of the heating zones is 3 m.

The paste transfer rate is 1.17 mg/cm².

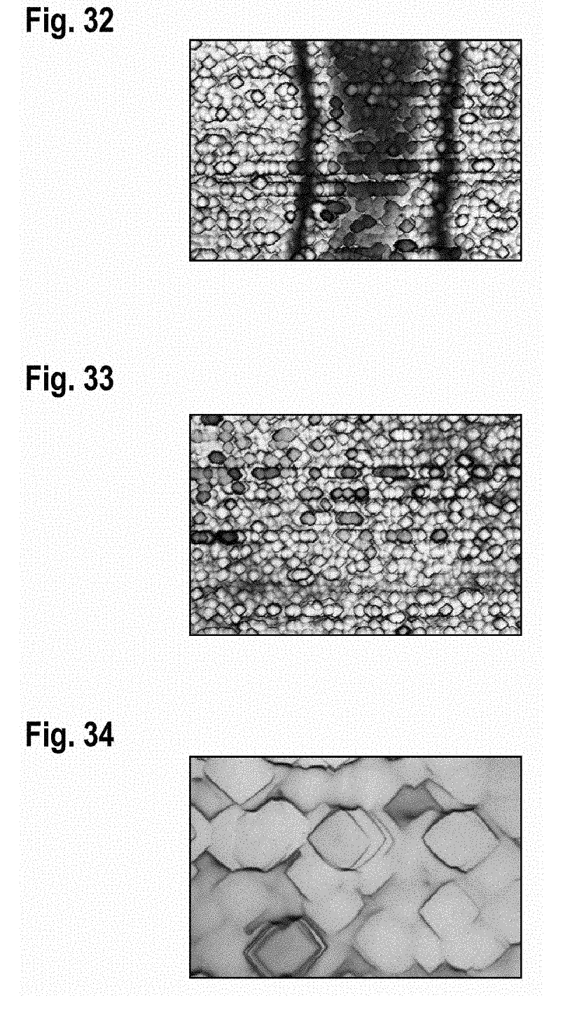

FIG. 32 shows a photomicrograph of a line which has been screen-printed with a doping paste according to Example 8 and dried.

FIG. 33 shows a photomicrograph of a paste area which has been screen-printed with a doping paste according to Example 8 and dried.

FIG. 34 shows a photomicrograph of a paste area which has been screen-printed with a doping paste according to Example 8 and dried.

### Example 9

72.5 g of ethylene glycol monobutyl ether (EGB), 2.9 g of dimethyldimethoxysilane and 12.8 g of aluminium tri-sec-butylate (ASB) are initially introduced in a glass flask and stirred until a homogeneous mixture forms. 12.2 g of glacial acetic acid and 1.4 g of 1,3-cyclohexanedione are added to this mixture in the said sequence with stirring. 1.9 g of water, dissolved in 5 g of EGB, are subsequently added dropwise, and the mixture is refluxed at 80° C. for four hours. After the warming, the hybrid sol is subjected to vacuum distillation at 70° C. for two hours until a final pressure of 20 mbar has been reached. The mass loss of readily volatile reaction products is 20.8 g. 103 g of α-terpineol (isomer mixture) and 3.9 g of tetraacetoxy diborate are subsequently added to the distilled mixture and mixed intensively. A pseudoplastic and very readily printable, transparent paste forms. The viscosity of the paste is 19.3 Pa*s at a shear rate of 25 1/s and a temperature of 23° C. The paste is printed with the aid of a screen printer using a trampoline screen with stainless-steel fabric (400 mesh, 18 μm wire diameter, calendered, 8-12 μm emulsion on top of the fabric) onto wafers which have been subjected to alkaline polish-etching, using the following printing parameters: a screen separation of 2 mm, a printing speed of 200 mm/s, a flooding speed of likewise 200 mm/s, a doctor-blade pressure of 60 N during the printing operation and a doctor-blade pressure of 20 N during the flooding, and using a carbon fibre doctor blade with polyurethane rubber having a Shore hardness of 65°. The printed wafers are subsequently dried in a through-flow oven warmed to 400° C. The belt speed is 90 cm/s. The length of the heating zones is 3 m. The paste transfer rate is 1.15 mg/cm².

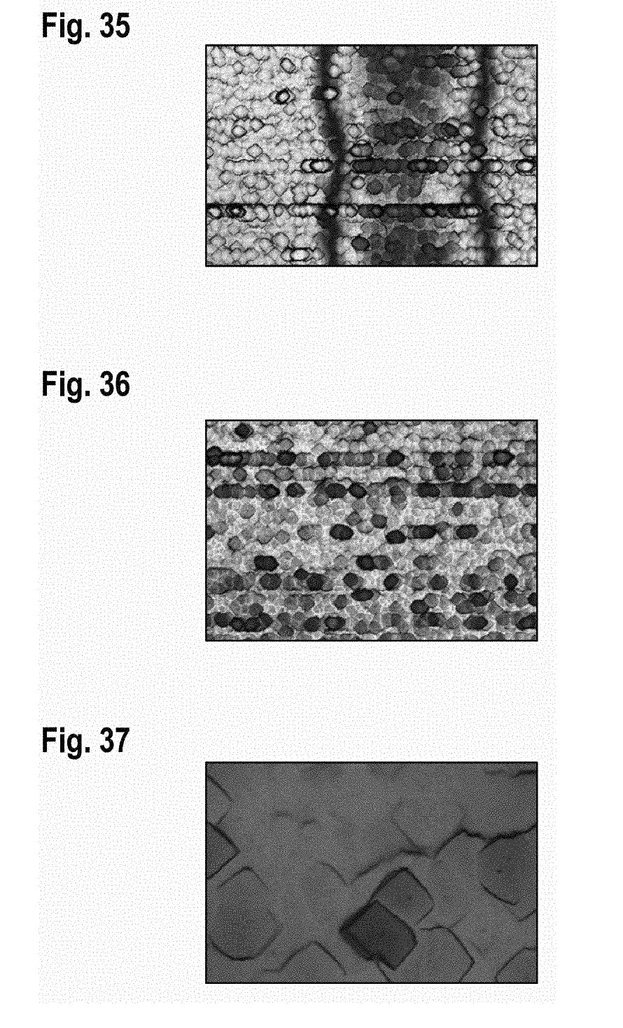

FIG. 35 shows a photomicrograph of a line which has been screen-printed with a doping paste according to Example 9 and dried.

FIG. 36 shows a photomicrograph of a paste area which has been screen-printed with a doping paste according to Example 9 and dried.

FIG. 37 shows a photomicrograph of a paste area which has been screen-printed with a doping paste according to Example 9 and dried.

### Example 10

74.2 g of ethylene glycol monobutyl ether (EGB), 2.9 g of dimethyldimethoxysilane and 12.9 g of aluminium tri-sec-butylate (ASB) are initially introduced in a glass flask and stirred until a homogeneous mixture forms. 12.3 g of glacial acetic acid and 1.9 g of 3,5-dihydroxybenzoic acid are added to this mixture in the said sequence with stirring. 1.9 g of water, dissolved in 5 g of EGB, are subsequently added dropwise, and the mixture is refluxed at 80° C. for four hours. After the warming, the hybrid sol is subjected to vacuum distillation at 70° C. for two hours until a final pressure of 20 mbar has been reached. The mass loss of readily volatile reaction products is 20.5 g. 96.5 g of α-terpineol (isomer mixture) and 3.9 g of tetraacetoxy diborate are subsequently added to the distilled mixture and mixed intensively. A pseudoplastic and very readily printable, transparent paste forms. The viscosity of the paste is 23.8 Pa*s at a shear rate of 25 1/s and a temperature of 23° C. The paste is printed with the aid of a screen printer using a trampoline screen with stainless-steel fabric (400 mesh, 18 μm wire diameter, calendered, 8-12 μm emulsion on top of the fabric) onto wafers which have been subjected to alkaline polish-etching, using the following printing parameters: a screen separation of 2 mm, a printing speed of 200 mm/s, a flooding speed of likewise 200 mm/s, a doctor-blade pressure of 60 N during the printing operation and a doctor-blade pressure of 20 N during the flooding, and using a carbon fibre doctor blade with polyurethane rubber having a Shore hardness of 65°. The printed wafers are subsequently dried in a through-flow oven warmed to 400° C. The belt speed is 90 cm/s. The length of the heating zones is 3 m. The paste transfer rate is 1.08 mg/cm².

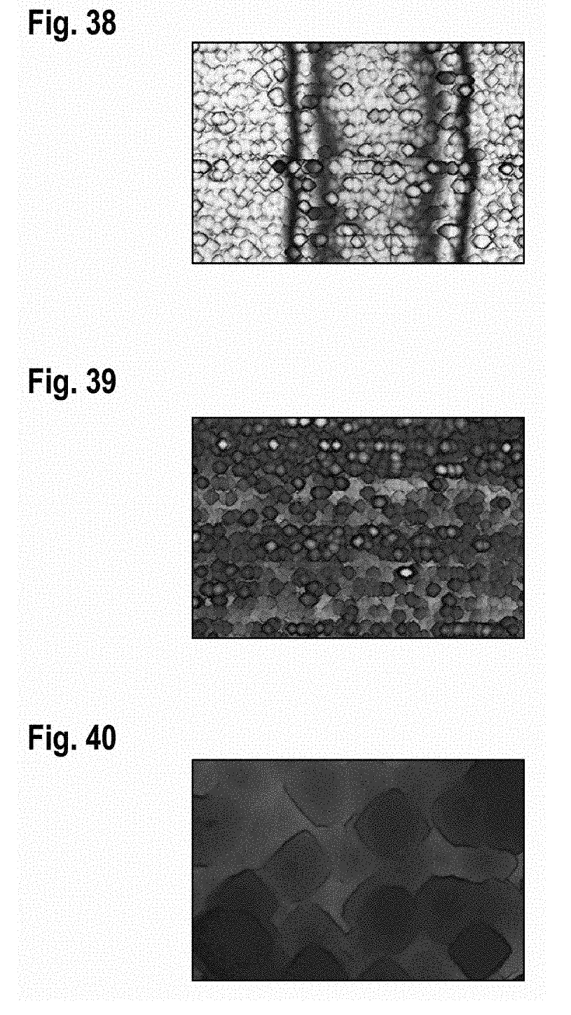

FIG. 38 shows a photomicrograph of a line which has been screen-printed with a doping paste according to Example 10 and dried.

FIG. 39 shows a photomicrograph of a paste area which has been screen-printed with a doping paste according to Example 10 and dried.

FIG. 40 shows a photomicrograph of a paste area which has been screen-printed with a doping paste according to Example 10 and dried.

### Example 11

72.2 g of ethylene glycol monobutyl ether (EGB), 2.9 g of dimethyldimethoxysilane and 12.8 g of aluminium tri-sec-butylate (ASB) are initially introduced in a glass flask and stirred until a homogeneous mixture forms. 12.3 g of glacial acetic acid and 1.6 g of salicylic acid are added to this mixture in the said sequence with stirring. 1.9 g of water, dissolved in 5 g of EGB, are subsequently added dropwise, and the mixture is refluxed at 80° C. for four hours. After the warming, the hybrid sol is subjected to vacuum distillation at 70° C. for two hours until a final pressure of 20 mbar has been reached. The mass loss of readily volatile reaction products is 16.9 g. 94.5 g of α-terpineol (isomer mixture) and 4 g of tetraacetoxy diborate are subsequently added to the distilled mixture and mixed intensively. A pseudoplastic and very readily printable, transparent paste forms. The viscosity of the paste is 8.4 Pa*s at a shear rate of 25 1/s and a temperature of 23° C. The paste is printed with the aid of a screen printer using a trampoline screen with stainless-steel fabric (400 mesh, 18 μm wire diameter, calendered, 8-12 μm emulsion on top of the fabric) onto wafers which have been subjected to alkaline polish-etching, using the following printing parameters: a screen separation of 2 mm, a printing speed of 200 mm/s, a flooding speed of likewise 200 mm/s, a doctor-blade pressure of 60 N during the printing operation and a doctor-blade pressure of 20 N during the flooding, and using a carbon fibre doctor blade with polyurethane rubber having a Shore hardness of 65°. The printed wafers are subsequently dried in a through-flow oven warmed to 400° C. The belt speed is 90 cm/s. The length of the heating zones is 3 m. The paste transfer rate is 0.92 mg/cm².

FIG. 41 shows a photomicrograph of a line which has been screen-printed with a doping paste according to Example 11 and dried.

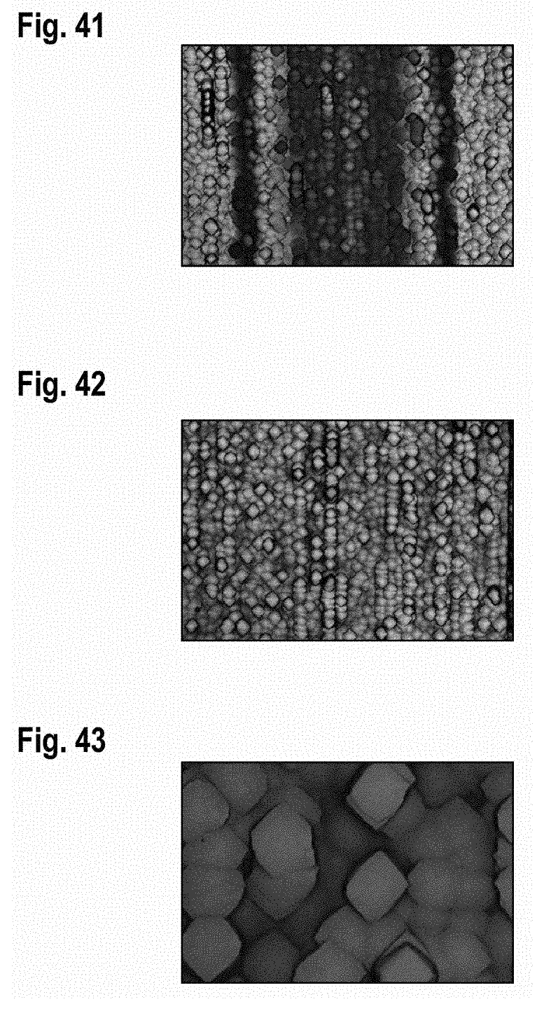

FIG. 42 shows a photomicrograph of a paste area which has been screen-printed with a doping paste according to Example 11 and dried.

FIG. 43 shows a photomicrograph of a paste area which has been screen-printed with a doping paste according to Example 11 and dried.

### Example 12

72.3 g of ethylene glycol monobutyl ether (EGB), 2.9 g of dimethyldimethoxysilane and 12.9 g of aluminium tri-sec-butylate (ASB) are initially introduced in a glass flask and stirred until a homogeneous mixture forms. 12.2 g of glacial acetic acid and 0.56 g of acetaldoxime are added to this mixture in the said sequence with stirring. 1.9 g of water, dissolved in 5 g of EGB, are subsequently added dropwise, and the mixture is refluxed at 80° C. for four hours. After the warming, the hybrid sol is subjected to vacuum distillation at 70° C. for two hours until a final pressure of 20 mbar has been reached. The mass loss of readily volatile reaction products is 21.6 g. 108 g of α-terpineol (isomer mixture) and 3.9 g of tetraacetoxy diborate are subsequently added to the distilled mixture and mixed intensively. A pseudoplastic and very readily printable, transparent paste forms. The viscosity of the paste is 9.3 Pa*s at a shear rate of 25 1/s and a temperature of 23° C. The paste is printed with the aid of a screen printer using a trampoline screen with stainless-steel fabric (400 mesh, 18 μm wire diameter, calendered, 8-12 μm emulsion on top of the fabric) onto wafers which have been subjected to alkaline polish-etching, using the following printing parameters: a screen separation of 2 mm, a printing speed of 200 mm/s, a flooding speed of likewise 200 mm/s, a doctor-blade pressure of 60 N during the printing operation and a doctor-blade pressure of 20 N during the flooding, and using a carbon fibre doctor blade with polyurethane rubber having a Shore hardness of 65°. The printed wafers are subsequently dried in a through-flow oven warmed to 400° C. The belt speed is 90 cm/s. The length of the heating zones is 3 m. The paste transfer rate is 1.06 mg/cm².

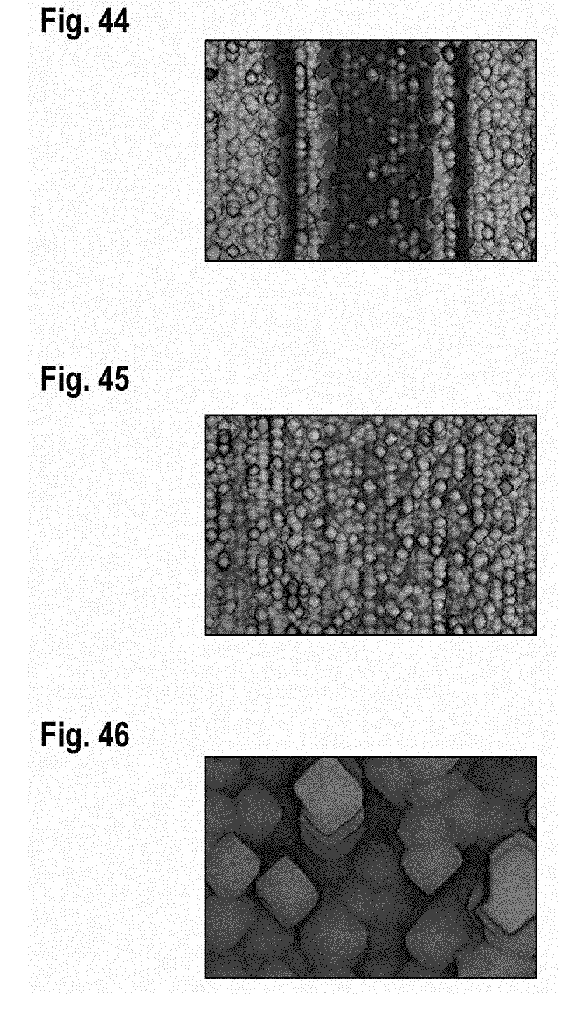

FIG. 44 shows a photomicrograph of a line which has been screen-printed with a doping paste according to Example 12 and dried.

FIG. 45 shows a photomicrograph of a paste area which has been screen-printed with a doping paste according to Example 12 and dried.

FIG. 46 shows a photomicrograph of a paste area which has been screen-printed with a doping paste according to Example 12 and dried.

### Example 13

72.1 g of ethylene glycol monobutyl ether (EGB), 2.9 g of dimethyldimethoxysilane and 12.8 g of aluminium tri-sec-butylate (ASB) are initially introduced in a glass flask and stirred until a homogeneous mixture forms. 12.3 g of glacial acetic acid and 1.1 g of acetaldoxime are added to this mixture in the said sequence with stirring. 1.9 g of water, dissolved in 5 g of EGB, are subsequently added dropwise, and the mixture is refluxed at 80° C. for four hours. After the warming, the hybrid sol is subjected to vacuum distillation at 70° C. for two hours until a final pressure of 20 mbar has been reached. The mass loss of readily volatile reaction products is 19.3 g. 99 g of α-terpineol (isomer mixture) and 3.9 g of tetraacetoxy diborate are subsequently added to the distilled mixture and mixed intensively. A pseudoplastic and very readily printable, transparent paste forms. The viscosity of the paste is 5.9 Pa*s at a shear rate of 25 1/s and a temperature of 23° C. The paste is printed with the aid of a screen printer using a trampoline screen with stainless-steel fabric (400 mesh, 18 μm wire diameter, calendered, 8-12 μm emulsion on top of the fabric) onto wafers which have been subjected to alkaline polish-etching, using the following printing parameters: a screen separation of 2 mm, a printing speed of 200 mm/s, a flooding speed of likewise 200 mm/s, a doctor-blade pressure of 60 N during the printing operation and a doctor-blade pressure of 20 N during the flooding, and using a carbon fibre doctor blade with polyurethane rubber having a Shore hardness of 65°. The printed wafers are subsequently dried in a through-flow oven warmed to 400° C. The belt speed is 90 cm/s. The length of the heating zones is 3 m. The paste transfer rate is 0.86 mg/cm².

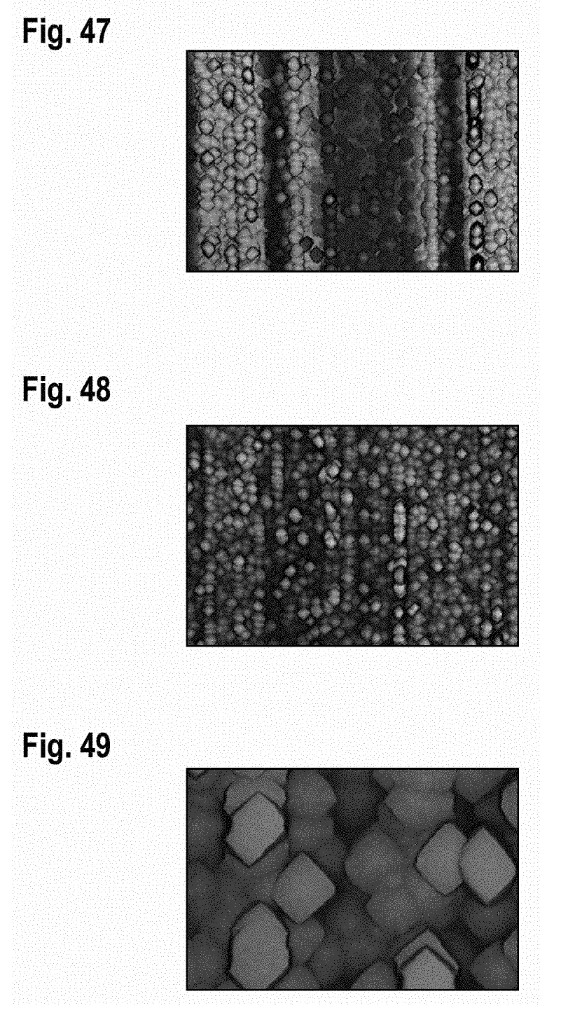

FIG. 47 shows a photomicrograph of a line which has been screen-printed with a doping paste according to Example 13 and dried.

FIG. 48 shows a photomicrograph of a paste area which has been screen-printed with a doping paste according to Example 13 and dried.

FIG. 49 shows a photomicrograph of a paste area which has been screen-printed with a doping paste according to Example 13 and dried.

### Example 14

577.2 g of ethylene glycol monobutyl ether (EGB), 19.9 g of tetraethyl orthosilicate, 19.9 g of 1,2-bis(triethoxysilyl)ethane and 102.2 g of aluminium tri-sec-butylate (ASB) are initially introduced in a glass flask and stirred until a homogeneous mixture forms. 97.8 g of glacial acetic acid and 6 g of acetaldoxime are added to this mixture in the said sequence with stirring. 15.6 g of water, dissolved in 50 g of EGB, are subsequently added dropwise, and the mixture is refluxed at 80° C. for four hours. After the warming, the hybrid sol is subjected to vacuum distillation at 70° C. for two hours until a final pressure of 20 mbar has been reached. The mass loss of readily volatile reaction products is 269.7 g. 782 g of α-terpineol (isomer mixture) and 32.2 g of tetraacetoxy diborate are subsequently added to the distilled mixture and mixed intensively, and finally a further 100 ml of ethylene glycol monobutyl ether are added. A pseudoplastic and very readily printable, transparent paste forms. The paste is printed with the aid of a screen printer using a trampoline screen with stainless-steel fabric (400 mesh, 18 μm wire diameter, calendered, 8-12 μm emulsion on top of the fabric) onto wafers which have been subjected to alkaline polish-etching, using the following printing parameters: a screen separation of 2 mm, a printing speed of 200 mm/s, a flooding speed of likewise 200 mm/s, a doctor-blade pressure of 60 N during the printing operation and a doctor-blade pressure of 20 N during the flooding, and using a carbon fibre doctor blade with polyurethane rubber having a Shore hardness of 65°. The printed wafers are subsequently dried in a through-flow oven warmed to 400° C. The belt speed is 90 cm/s. The length of the heating zones is 3 m.

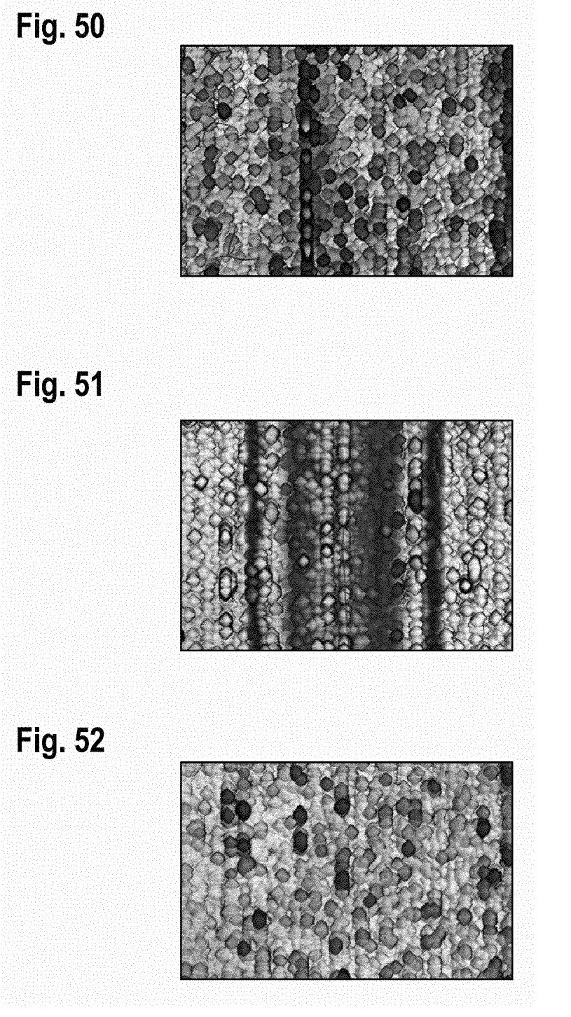

FIG. 50 shows a photomicrograph of a paste area which has been screen-printed with a doping paste according to Example 14 and dried.

### Example 15

60 g of ethylene glycol monobutyl ether (EGB), 1.7 g of tetraethyl orthosilicate, 1.4 g of 1,2-bis(triethoxysilyl)ethane, 1 g of dimethyldimethoxysilane and 12.8 g of aluminium tri-sec-butylate (ASB) are initially introduced in a glass flask and stirred until a homogeneous mixture forms. 12.4 g of glacial acetic acid and 0.7 g of acetaldoxime are added to this mixture in the said sequence with stirring. 1.9 g of water, dissolved in 17.5 g of EGB, are subsequently added dropwise, and the mixture is refluxed at 80° C. for four hours. After the warming, the hybrid sol is subjected to vacuum distillation at 70° C. for two hours until a final pressure of 20 mbar has been reached. The mass loss of readily volatile reaction products is 15.2 g. 85 g of α-terpineol (isomer mixture) and 4 g of tetraacetoxy diborate are subsequently added to the distilled mixture and mixed intensively, and finally a further 100 ml of ethylene glycol monobutyl ether are added. A pseudoplastic and very readily printable, transparent paste forms. The paste is printed with the aid of a screen printer using a trampoline screen with stainless-steel fabric (400 mesh, 18 μm wire diameter, calendered, 8-12 μm emulsion on top of the fabric) onto wafers which have been subjected to alkaline polish-etching, using the following printing parameters: a screen separation of 2 mm, a printing speed of 200 mm/s, a flooding speed of likewise 200 mm/s, a doctor-blade pressure of 60 N during the printing operation and a doctor-blade pressure of 20 N during the flooding, and using a carbon fibre doctor blade with polyurethane rubber having a Shore hardness of 65°. The printed wafers are subsequently dried in a through-flow oven warmed to 400° C. The belt speed is 90 cm/s. The length of the heating zones is 3 m.

FIG. 51 shows a photomicrograph of a line which has been screen-printed with a doping paste according to Example 15 and dried.

FIG. 52 shows a photomicrograph of a paste area which has been screen-printed with a doping paste according to Example 15 and dried.

### Example 16

72 g of ethylene glycol monobutyl ether (EGB), 1.3 g of 1,2-bis(triethoxysilyl)ethane, 2 g of dimethyldimethoxysilane and 12.8 g of aluminium tri-sec-butylate (ASB) are initially introduced in a glass flask and stirred until a homogeneous mixture forms. 12.2 g of glacial acetic acid and 0.7 g of acetaldoxime are added to this mixture in the said sequence with stirring. 1.9 g of water, dissolved in 5 g of EGB, are subsequently added dropwise, and the mixture is refluxed at 80° C. for four hours. After the warming, the hybrid sol is subjected to vacuum distillation at 70° C. for two hours until a final pressure of 20 mbar has been reached. The mass loss of readily volatile reaction products is 15.3 g. 92 g of α-terpineol (isomer mixture) and 3.9 g of tetraacetoxy diborate are subsequently added to the distilled mixture and mixed intensively, and finally a further 100 ml of ethylene glycol monobutyl ether are added. A pseudoplastic and very readily printable, transparent paste forms. The viscosity of the paste is 10.6 Pa*s at a shear rate of 25 1/s and a temperature of 23° C. The paste is printed with the aid of a screen printer using a trampoline screen with stainless-steel fabric (400 mesh, 18 μm wire diameter, calendered, 8-12 μm emulsion on top of the fabric) onto wafers which have been subjected to alkaline polish-etching, using the following printing parameters: a screen separation of 2 mm, a printing speed of 200 mm/s, a flooding speed of likewise 200 mm/s, a doctor-blade pressure of 60 N during the printing operation and a doctor-blade pressure of 20 N during the flooding, and using a carbon fibre doctor blade with polyurethane rubber having a Shore hardness of 65°. The printed wafers are subsequently dried in a through-flow oven warmed to 400° C. The belt speed is 90 cm/s. The length of the heating zones is 3 m.

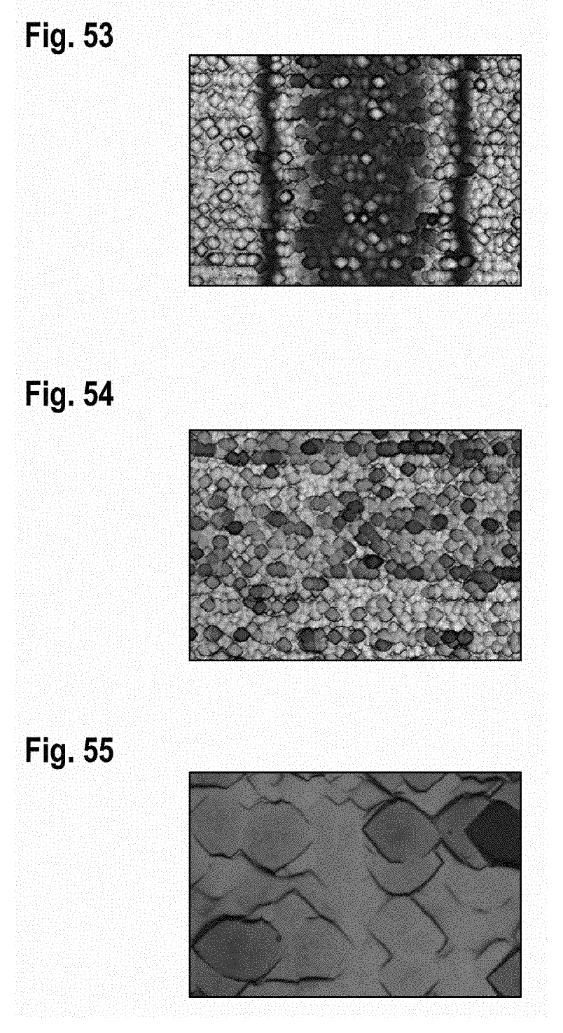

FIG. 53 shows a photomicrograph of a line which has been screen-printed with a doping paste according to Example 16 and dried.

FIG. 54 shows a photomicrograph of a paste area which has been screen-printed with a doping paste according to Example 16 and dried.

FIG. 55 shows a photomicrograph of a paste area which has been screen-printed with a doping paste according to Example 16 and dried.

### Example 17

72.2 g of ethylene glycol monobutyl ether (EGB), 0.4 g of 1,2-bis(triethoxysilyl)ethane, 2.6 g of dimethyldimethoxysilane and 12.9 g of aluminium tri-sec-butylate (ASB) are initially introduced in a glass flask and stirred until a homogeneous mixture forms. 12.4 g of glacial acetic acid and 0.7 g of acetaldoxime are added to this mixture in the said sequence with stirring. 1.9 g of water, dissolved in 5 g of EGB, are subsequently added dropwise, and the mixture is refluxed at 80° C. for four hours. After the warming, the hybrid sol is subjected to vacuum distillation at 70° C. for two hours until a final pressure of 20 mbar has been reached. The mass loss of readily volatile reaction products is 15.3 g. 92 g of α-terpineol (isomer mixture) and 4 g of tetraacetoxy diborate are subsequently added to the distilled mixture and mixed intensively, and finally a further 100 ml of ethylene glycol monobutyl ether are added. A pseudoplastic and very readily printable, transparent paste forms. The viscosity of the paste is 5.4 Pa*s at a shear rate of 25 1/s and a temperature of 23° C. The paste is printed with the aid of a screen printer using a trampoline screen with stainless-steel fabric (400 mesh, 18 μm wire diameter, calendered, 8-12 μm emulsion on top of the fabric) onto wafers which have been subjected to alkaline polish-etching, using the following printing parameters: a screen separation of 2 mm, a printing speed of 200 mm/s, a flooding speed of likewise 200 mm/s, a doctor-blade pressure of 60 N during the printing operation and a doctor-blade pressure of 20 N during the flooding, and using a carbon fibre doctor blade with polyurethane rubber having a Shore hardness of 65°. The printed wafers are subsequently dried in a through-flow oven warmed to 400° C. The belt speed is 90 cm/s. The length of the heating zones is 3 m.

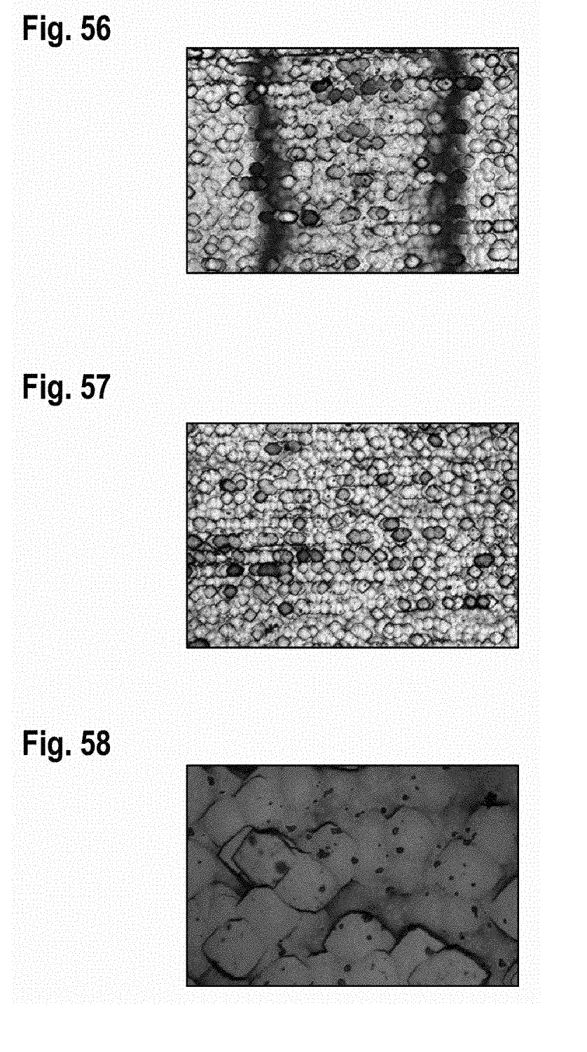

FIG. 56 shows a photomicrograph of a line which has been screen-printed with a doping paste according to Example 17 and dried.

FIG. 57 shows a photomicrograph of a paste area which has been screen-printed with a doping paste according to Example 17 and dried.

FIG. 58 shows a photomicrograph of a paste area which has been screen-printed with a doping paste according to Example 17 and dried.

### Example 18

72.2 g of ethylene glycol monobutyl ether (EGB), 3.55 g of trimethoxyvinylsilane and 12.9 g of aluminium tri-sec-butylate (ASB) are initially introduced in a glass flask and stirred until a homogeneous mixture forms. 12.4 g of glacial acetic acid and 0.7 g of acetaldoxime are added to this mixture in the said sequence with stirring. 1.9 g of water, dissolved in 5 g of EGB, are subsequently added dropwise, and the mixture is refluxed at 80° C. for four hours. After the warming, the hybrid sol is subjected to vacuum distillation at 70° C. for two hours until a final pressure of 20 mbar has been reached. 97 g of α-terpineol (isomer mixture) and 4 g of tetraacetoxy diborate are subsequently added to the distilled mixture and mixed intensively. A pseudoplastic and very readily printable, transparent paste forms.

### Example 19

72.2 g of ethylene glycol monobutyl ether (EGB), 5.85 g of dimethoxydiphenylsilane and 12.9 g of aluminium tri-sec-butylate (ASB) are initially introduced in a glass flask and stirred until a homogeneous mixture forms. 12.4 g of glacial acetic acid and 0.7 g of acetaldoxime are added to this mixture in the said sequence with stirring. 1.9 g of water, dissolved in 5 g of EGB, are subsequently added dropwise, and the mixture is refluxed at 80° C. for four hours. After the warming, the hybrid sol is subjected to vacuum distillation at 70° C. for two hours until a final pressure of 20 mbar has been reached. 97 g of α-terpineol (isomer mixture) and 4 g of tetraacetoxy diborate are subsequently added to the distilled mixture and mixed intensively. A pseudoplastic and very readily printable, transparent paste forms.

### Example 20

72.2 g of ethylene glycol monobutyl ether (EGB), 3.53 g of bis(dimethoxy-dimethylsilyl)-1,2-ethane and 12.9 g of aluminium tri-sec-butylate (ASB) are initially introduced in a glass flask and stirred until a homogeneous mixture forms. 12.4 g of glacial acetic acid and 0.7 g of acetaldoxime are added to this mixture in the said sequence with stirring. 1.9 g of water, dissolved in 5 g of EGB, are subsequently added dropwise, and the mixture is refluxed at 80° C. for four hours. After the warming, the hybrid sol is subjected to vacuum distillation at 70° C. for two hours until a final pressure of 20 mbar has been reached. 97 g of α-terpineol (isomer mixture) and 4 g of tetraacetoxy diborate are subsequently added to the distilled mixture and mixed intensively. A pseudoplastic and very readily printable, transparent paste forms.

### Example 21

72.2 g of ethylene glycol monobutyl ether (EGB), 4.36 g of dimethoxymethyl-phenylsilane and 12.9 g of aluminium tri-sec-butylate (ASB) are initially introduced in a glass flask and stirred until a homogeneous mixture forms. 12.4 g of glacial acetic acid and 0.7 g of acetaldoxime are added to this mixture in the said sequence with stirring. 1.9 g of water, dissolved in 5 g of EGB, are subsequently added dropwise, and the mixture is refluxed at 80° C. for four hours. After the warming, the hybrid sol is subjected to vacuum distillation at 70° C. for two hours until a final pressure of 20 mbar has been reached. 97 g of α-terpineol (isomer mixture) and 4 g of tetraacetoxy diborate are subsequently added to the distilled mixture and mixed intensively. A pseudoplastic and very readily printable, transparent paste forms.

### Example 22

72.2 g of ethylene glycol monobutyl ether (EGB), 5.8 g of triethoxyphenylsilane and 12.9 g of aluminium tri-sec-butylate (ASB) are initially introduced in a glass flask and stirred until a homogeneous mixture forms. 12.4 g of glacial acetic acid and 0.7 g of acetaldoxime are added to this mixture in the said sequence with stirring. 1.9 g of water, dissolved in 5 g of EGB, are subsequently added dropwise, and the mixture is refluxed at 80° C. for four hours. After the warming, the hybrid sol is subjected to vacuum distillation at 70° C. for two hours until a final pressure of 20 mbar has been reached. 97 g of α-terpineol (isomer mixture) and 4 g of tetraacetoxy diborate are subsequently added to the distilled mixture and mixed intensively. A pseudoplastic and very readily printable, transparent paste forms.

1. Printable hybrid sols and/or gels based on precursors of inorganic oxides which are printed selectively onto suitable surfaces of the substrate by means of suitable printing processes on silicon surfaces for the purposes of local and/or full-area diffusion and doping on one side for the production of solar cells, dried and subsequently brought to specific doping of the substrate itself by means of a suitable high-temperature process for release of the boron oxide precursor present in the hybrid gel to the substrate located beneath the hybrid gel.

2. Hybrid sols and/or gels according to claim 1, characterised in that they are compositions based on precursors of silicon dioxide, aluminium oxide and boron oxide.

3. Hybrid sols and/or gels according to claim 1, characterised in that they are compositions based on precursors of silicon dioxide, aluminium oxide and boron oxide which are employed as a mixture.

4. Printable hybrid sols and/or gels according to claim 1, characterised in that they have been obtained on the basis of precursors of silicon dioxide, selected from the group of symmetrically or asymmetrically mono- to tetrasubstituted carboxy-, alkoxy- and alkoxyalkylsilanes, in particular alkylalkoxysilanes in which at least one hydrogen atom is bonded to the central silicon atom, carboxy-, alkoxy- and alkoxyalkylsilanes, in particular alkylalkoxysilanes, which contain individual or different saturated, unsaturated branched, unbranched aliphatic, alicyclic and aromatic radicals, which may in turn be functionalised at any desired position of the alkyl, alkoxide or carboxyl radical by heteroatoms selected from the group O, N, S, Cl and Br, and mixtures of these precursors.

5. Printable hybrid sols and/or gels according to claim 1, characterised in that they have been obtained on the basis of precursors of silicon dioxide, selected from the group triethoxysilane, tetraethyl orthosilicate, triethoxysilane, ethoxytrimethylsilane, dimethyldimethoxysilane, dimethyldiethoxysilane, triethoxyvinylsilane, bis[triethoxysilyl]ethane and bis[diethoxymethylsilyl]ethane, and mixtures thereof.

6. Printable hybrid sols and/or gels according to claim 1, characterised in that they have been obtained on the basis of precursors of aluminium oxide, selected from the group of symmetrically and asymmetrically substituted aluminium alcoholates (alkoxides), aluminium tris(β-diketones), aluminium tris(β-ketoesters), aluminium soaps, aluminium carboxylates, and mixtures thereof.

7. Printable hybrid sols and/or gels according to claim 1, characterised in that they have been obtained on the basis of precursors of aluminium oxide, selected from the group aluminium triethanolate, aluminium triisopropylate, aluminium tri-sec-butylate, aluminium tributylate, aluminium triamylate and aluminium triisopentanolate, aluminium acetylacetonate or aluminium tris(1,3-cyclohexanedionate), aluminium mono-acetylacetonate monoalcoholate, aluminium tris(hydroxyquinolate), mono- and dibasic aluminium stearate and aluminium tristearate, aluminium acetate, aluminium triacetate, basic aluminium formate, aluminium triformate and aluminium trioctanoate, aluminium hydroxide, aluminium metahydroxide and aluminium trichloride, and mixtures thereof.

8. Printable hybrid sols and/or gels according to claim 1, characterised in that they have been obtained on the basis of precursors of boron oxide, selected from the group of alkyl borates, boric acid esters of functionalised 1,2-glycols, boric acid esters of alkanolamines, mixed anhydrides of boric acid and carboxylic acids, and mixtures thereof.

9. Printable hybrid sols and/or gels according to claim 1, characterised in that they have been obtained on the basis of precursors of boron oxide, selected from the group boron oxide, diboron oxide, triethyl borate, triisopropyl borate, boric acid glycol ester, boric acid ethylene glycol ester, boric acid glycerol ester, boric acid ester of 2,3-dihydroxysuccinic acid, tetraacetoxy diborate, and boric acid esters of the alkanolamines ethanolamine, diethanolamine, triethanolamine, propanolamine, dipropanolamine and tripropanolamine.

10. Printable hybrid sols and/or gels obtainable by bringing precursors of claim 4 to partial or complete intra- and/or interspecies condensation under water-containing or anhydrous conditions with the aid of the sol-gel technique, either simultaneously or sequentially, forming storage-stable, very readily printable and printing-stable formulations.

11. Printable hybrid sols and/or gels according to claim 10, obtainable by removal of the volatile reaction assistants and by-products during the condensation reaction.

12. Printable hybrid sols and/or gels according to claim 10, obtainable by adjustment of the precursor concentrations, the water and catalyst content and the reaction temperature and time.

13. Printable hybrid sols and/or gels according to claim 10, obtainable by specific addition of condensation-controlling agents in the form of complexing agents and/or chelating agents, various solvents in defined amounts, based on the total volume, whereby the degree of gelling of the hybrid sols and gels formed is specifically controlled.

14. Use of the printable hybrid sols and/or gels according to claim 1 in a process for the production of solar cells, in which they are processed and deposited by means of a printing process selected from spin or dip coating, drop casting, curtain or slot-die coating, screen or flexographic printing, gravure, ink-jet or aerosol-jet printing, offset printing, microcontact printing, electrohydrodynamic dispensing, roller or spray coating, ultrasound spray coating, pipe-jet printing, laser transfer printing, pad printing, flat-bed screen printing and rotary screen printing.

15. Use of the printable hybrid sols and/or gels according to claim 1 for the processing of silicon wafers for photovoltaic, microelectronic, micromechanical and micro-optical applications.

16. Use of the printable hybrid sols and/or gels according to claim 1 for the production of PERC, PERL, PERT and IBC solar cells and others, where the solar cells have further architectural features, such as MWT, EWT, selective emitter, selective front surface field, selective back surface field and bifaciality.

17. Use of the printable hybrid sols and/or gels according to claim 1 as boron-containing doping medium for silicon, where the medium simultaneously acts as diffusion barrier or as diffusion-inhibiting layer against undesired diffusion of phosphorus through this medium and completely blocks or sufficiently inhibits the latter so that the doping prevailing beneath these printed-on media is p-type, i.e. boron-containing.

18. Use according to claim 17, characterised in that doping of the printed substrate is carried out by suitable temperature treatment and doping of the unprinted silicon wafer surfaces with dopants of the opposite polarity is induced simultaneously and/or sequentially by means of conventional gas-phase diffusion, where the printed-on hybrid sols and/or gels act as diffusion barrier against the dopants of the opposite polarity.

19. Process for the doping of silicon wafers, characterised in that
a) silicon wafers are printed locally on one or both sides or over the entire surface on one side with the hybrid sols and/or gels according to claim 1, the printed-on medium is dried, compacted and subsequently subjected to subsequent gas-phase diffusion with, for example, phosphoryl chloride, giving p-type dopings in the printed regions and n-type dopings in the regions subjected exclusively to gas-phase diffusion,
or
b) hybrid sol and/or gel according to claim 1 deposited over a large area on the silicon wafer is compacted and local doping of the underlying substrate material is initiated from the dried and/or compacted medium with the aid of laser irradiation, followed by high-temperature treatment, inducing diffusion and doping for the production of two-stage p-type doping levels in the silicon,
or
c) the silicon wafer is printed locally on one side with hybrid sols and/or gels according to claim 1, where the structured deposition may optionally have alternating lines, the printed structures are dried and compacted, and the silicon wafer is subsequently coated over the entire surface on the same side of the wafer with the aid of PVD- and/or CVD-deposited phosphorus-doping dopant sources, where the printed structures of the hybrid sols and/or gels are encapsulated, and the entire overlapping structure is brought to structured doping of the silicon wafer by suitable high-temperature treatment, where the printed-on hybrid gel acts as diffusion barrier against the phosphorus-containing dopant source located on top and the dopant present therein,
or
d) the silicon wafer is printed locally on one side with hybrid sols and/or gels according to claim 1, where the structured deposition may optionally have alternating lines, the printed structures are dried and compacted, and the silicon wafer is subsequently coated over the entire surface on the same side of the wafer with the aid of doping inks or doping pastes which have a phosphorus-doping action, where the printed structures of the hybrid sols and gels are encapsulated, and the entire overlapping structure is brought to structured doping of the silicon wafer by suitable high-temperature treatment, where the printed-on hybrid gel acts as diffusion barrier against the phosphorus-containing dopant source located on top and the dopant present therein.
